(19) United States
(12) Patent Application Publication
(10) Pub. No.: US 2011/0297988 A1
(43) Pub. Date: Dec. 8, 2011

(54) TRANSPARENT SUBSTRATE FOR PHOTONIC DEVICES

(75) Inventors: Benoit Domercq, Jumet (BE); Philippe Roquiny, Jumet (BE); Daniel Decroupet, Jumet (BE)

(73) Assignee: AGC Glass Europe, Bruxelles (Watermael-Boitsfort) (BE)

(21) Appl. No.: 13/201,765

(22) PCT Filed: Feb. 19, 2010
(86) PCT No.: PCT/EP2010/052147

§ 371 Date: Aug. 16, 2011

(30) Foreign Application Priority Data
Feb. 19, 2009 (BE) BE 2009/0094
Feb. 19, 2009 (BE) BE 2009/0095
Feb. 19, 2009 (BE) BE 2009/0096
Feb. 19, 2009 (BE) BE 2009/0097
Feb. 19, 2009 (BE) BE 2009/0098
Feb. 19, 2009 (BE) BE2009/0099
Sep. 8, 2009 (BE) BE 2009/0548

(51) Int. Cl. H01L 33/58; B05D 5/12; B05D 5/06

(52) U.S. Cl. 257/98; 427/64; 257/E33.073

(57) ABSTRACT

Transparent substrate (1) for photonic devices comprising a support (10) and an electrode (11), said electrode (11) comprising a lamination structure comprising a single metal conduction layer (112) and at least one coating (110) having properties for improving the light transmission through said electrode, wherein said coating (110) has a geometric thickness at least more than 3.0 nm and at most less than or equal to 200 nm, and said coating (110) comprises at least one layer for improving light transmission (1101) and is located between the metal conduction layer (112) and the support (10), on which said electrode (11) is deposited, said transparent substrate (1) is such in that the optical thickness of the coating having properties for improving the light transmission (110), T_{D1}, and the geometric thickness of the metal conduction layer (112), T_{ME}, are linked by the equation:

T_{ME}=T_{ME}_{_{—}}ₒ+[B*sin(π*T_{D1}/T_{D1}_{_{—}}ₒ)]/(nₛᵤₚₚₒᵣₜ)³

where T_{ME}ₒ, B and T_{D1}_{_{—}}ₒ are constants with T_{ME}_{_{—}}ₒ having a value in the range of 10.0 to 25.0 nm, B having a value in the range of 10.0 to 16.5 nm and T_{D1}_{_{—}}ₒ having a value in the range of 23.9*n_{D1}, to 28.3*n_{D1} nm, with n_{D1} representing the refractive index of the coating for improving the light transmission at a wavelength of 550 nm and nₛᵤₚₚₒᵣₜ represents the refractive index of the support at a wavelength of 550 nm.

The present invention involves the technical field of photonic devices. The present invention relates to a transparent substrate for photonic devices, to the process for the manufacture of the substrate and also to the process for the manufacture of the photonic device that it is incorporated into. Photonic device is understood to mean any type of device that can emit or collect light. Such devices are optoelectronic devices, for example, such as organic light-emitting devices (OLED) or light collectors such as organic photovoltaic cells, also referred to as solar cells. In particular, the invention relates to a transparent substrate for an organic light-emitting device (OLED).

Organic light-emitting devices are manufactured with a good internal light efficiency. This efficiency is expressed in terms of internal quantum efficiency (IQE). Internal quantum efficiency represents the number of photons obtained by the injection of an electron. It lies in the order of 85%, even close to 100%, in known organic light-emitting devices. However, the efficiency of these devices is clearly limited by the losses associated with interface reflection phenomena.

In general, an OLED comprises at least one organic light-emitting layer, a transparent conductor electrode generally made from indium-doped tin oxide (ITO) and a transparent support for supporting the electrode. The support is made, for example, of glass, ceramic glass or polymer film. The refractive indexes of the different constituents of the OLED lie in the range of 1.6-1.8 for the organic layers of the light-emitting device, 1.6 to 2 for the ITO layer, 1.4 to 1.6 for the supporting substrate and 1.0 for the outside air. The losses as a result of reflection (R) occur at the interfaces and cause a reduction in external quantum efficiency (EQE). The external quantum efficiency is equal to the internal quantum efficiency minus the losses through reflection.

Indium-doped tin oxide (ITO) is the material most widely used to form transparent electrodes. However, its use unfortunately causes some problems. In fact, indium resources are limited, which in the short term will lead to an inevitable increase in production costs for these devices. Moreover, because of the resistivity of ITO it is essential to use a thick layer to obtain a sufficiently conductive electrode. Since ITO is slightly absorbent, this causes problems of decreasing transparency. Moreover, thick ITO is generally more crystalline, and this increases the roughness of the surface, which must then be polished occasionally for use within organic light-emitting devices. Furthermore, indium present in organic light-emitting devices has a tendency to diffuse into the organic part of these devices resulting in a reduction in the service life of these devices.

Document WO 2008/029060 A2 discloses a transparent substrate, in particular a transparent glass substrate, having a multilayer electrode with a complex lamination structure comprising a metal conductive layer and also having a base layer combining the properties of a barrier layer and an antireflective layer. This type of electrode enables layers with a low resistivity and a transparency at least equal to the electrode of ITO to be obtained, and these electrodes can be advantageously used in the field of large-surface light sources such as light panels. Moreover, these electrodes allow the quantity of indium used in their formation to be reduced and even dispensed with. However, although an antireflective layer in the form of a barrier layer is used, the solutions proposed in document WO 2008/029060 A2 do not seek in any way to optimise the amount of light emitted by an OLED limiting the losses associated with interface reflection phenomena.

The first aim set by the present invention is to provide a transparent substrate that allows an increase in the amount of light transmitted through the substrate to be obtained, in other words an increase in the amount of light emitted or converted by a photonic device that it is incorporated into, i.e. in the case of a monochromic radiation. The term “monochromic” is understood to mean that a single colour (e.g. red, green, blue, white . . . ) is perceived by the eye without this light being monochromatic as such. In other words, monochromic radiation denotes a radiation covering a wavelength range. More specifically, it concerns providing a transparent substrate that allows an increase in the amount of light emitted by an organic light-emitting device that it is incorporated into to be achieved, i.e. in the case of a monochromic radiation.

The second aim set by the present invention is to provide a process for the manufacture of a transparent substrate that has an improved light transmission.

The third aim set by the present invention is to provide a photonic device that incorporates the transparent substrate. More specifically, it is a matter of providing an organic light-emitting device that incorporates the transparent substrate, in particular an organic light-emitting device that emits quasi-white light.

The invention relates to a transparent substrate for photonic devices comprising a support and an electrode, said electrode comprising a lamination structure comprising a single metal conduction layer and at least one coating having properties for improving the light transmission through said electrode, wherein said coating has a geometric thickness at least more than 3.0 nm and at most less than or equal to 200 nm, preferably less than or equal to 170 nm, more preferred less than or equal to 130 nm, and said coating comprises at least one layer for improving light transmission and is located between the metal conduction layer and the support, on which said electrode is deposited, characterised in that the optical thickness of the coating having properties for improving the light transmission, T_{D1}, and the geometric thickness of the metal conduction layer, T_{ME}, are linked by the equation:

T_{ME}=T_{ME}_{_{—}}ₒ+[B*sin(π*T_{D1}T_{D1}_{_{—}}ₒ)]/nₛᵤₚₚₒᵣₜ)³

where T_{ME}_{_{—}}ₒ, B and T_{D1}_{_{—}}ₒ are constants with T_{ME}_{_{—}}ₒ having a value in the range of 10.0 to 25.0 nm, B having a value in the range of 10.0 to 16.5 nm and T_{D1}_{_{—}}ₒ having a value in the range of 23.9*n_{D1} to 28.3*n_{D1} nm, with n_{D1} representing the refractive index of the coating for improving the light transmission at a wavelength of 550 nm and nₛᵤₚₚₒᵣₜ represents the refractive index of the support at a wavelength of 550 nm. Preferably, constants T_{ME}_{_{—}}ₒ, B and T_{D1}_{_{—}}ₒ are such that T_{ME}_{_{—}}ₒ has a value in the range of 11.5 to 22.5 nm, B has a value in the range of 12 to 15 and T_{D1}_{_{—}}₀ has a value in the range of 24.8*n_{D1} to 27.3*n_{D1} nm. More preferred, constants T_{ME}_{_{—}}ₒ, B and T_{D1}_{_{—}}ₒ are such that T_{ME}_{_{—}}ₒ has a value in the range of 12.0 to 22.5 nm, B has a value in the range of 12 to 15 and T_{D1}_{_{—}}ₒ has a value in the range of 24.8*n_{D1} to 27.3*n_{D1} nm.

The advantage provided by the substrate according to the invention is that it allows an increase in the amount of light emitted or converted by a photonic device that incorporates it to be obtained, i.e. in the case of monochromic radiation, and more particularly allows an increase in the amount of light emitted in the case of an organic light-emitting device (OLED). Moreover, in the case of an organic light-emitting device emitting white light, the substrate according to the invention can be used with any known type of layered lamination forming the organic part of the OLED that emits white light.

The substrate of the present invention will be considered to be transparent when it exhibits a light absorption of at most 50%, even at most 30%, preferably at most 20%, more preferred at most 10% at wavelengths in the visible light range.

The substrate of the present invention comprises an electrode, wherein said electrode can act as an anode or conversely as a cathode, depending on the type of device it is inserted into.

The expression “a coating having properties for improving light transmission” is understood to denote a coating whose presence in the lamination structure forming the electrode leads to an increase in the amount of light transmitted through the substrate, e.g. a coating having antireflective properties. In other words, a photonic device incorporating the substrate according to the invention emits or converts a more significant amount of light compared to a photonic device of the same type, but having a classic electrode (e.g.: ITO) deposited on an identical support to that of the substrate according to the invention. More particularly, when the substrate is inserted into an organic light-emitting device, the increase in the amount of light emitted is characterised by a higher luminance value, irrespective of the colour of the emitted light.

The geometric thickness of the coating for improving light transmission must have a thickness at least greater than 3 nm, preferably at least equal to 5 nm, more preferred at least equal to 7 nm, most preferred at least equal to 10 nm. For example, when the coating for improving light transmission is based on zinc oxide or on zinc oxide under-stoichiometric in oxygen, ZnOₓ, wherein these zinc oxides are possibly doped or alloyed with tin, a geometric thickness of the coating for improving light transmission of at least more than 3 nm allows a metal conduction layer, particularly of silver, that has a good conductivity to be obtained. The geometric thickness of the coating for improving light transmission advantageously has a thickness of less than or equal to 200 nm, preferably less than or equal to 170 nm, more preferred less than or equal to 130 nm, and the advantage of such thicknesses lies in the fact that the production process of said coating is quicker.

In a particular embodiment the substrate according to the invention comprises a transparent support having a refractive index at least equal to 1.2, preferably at least equal to 1.4, more preferred at least equal to 1.5 at a wavelength of 550 nm. The advantage provided by using a support with a high refractive index is that it allows the amount of transmitted or emitted light to be increased with the same substrate structure.

The term “support” is also understood to mean not only the support as such, but also any structure comprising the support as well as at least one layer of a material with a refractive index, n_{material,} close to the refractive index of the support, nₛᵤₚₚₒᵣₜ) in other words |nₛᵤₚₚₒᵣₜ−nₘₐₜₑᵣᵢₐₗ|≦0.1.|nₛᵤₚₚₒᵣₜ−nₘₐₜₑᵣᵢₐₗ| represents the absolute value of the difference between the refractive indexes. A silicon oxide layer deposited on a soda-lime-silica glass support can be cited as example.

The function of the support is to support and/or protect the electrode. The support can be made of glass, rigid plastic material (e.g. organic glass, polycarbonate) or flexible polymer films (e.g. polyvinyl chloride (PVC), polyethylene terephthalate (PET), polypropylene (PP)). The support is preferably rigid.

If the support is a polymer film, this preferably has a high refractive index, wherein the refractive index of the support (nₛᵤₚₚₒᵣₜ) has a value at least equal to 1.4, preferably at least equal to 1.5, more preferred at least equal to 1.6, most preferred at least equal to 1.7. nₛᵤₚₚₒᵣₜ represents the refractive index of the support at a wavelength of 550 nm. The advantage provided by using a support with a high refractive index is that it allows the amount of transmitted or emitted light to be increased with the same electrode structure.

If the support is made of glass, e.g. a sheet of glass, this preferably has a geometric thickness of at least 0.35 mm. The term “geometric thickness” is understood to mean the average geometric thickness. Glasses are mineral or organic. Mineral glasses are preferred. Of these, soda-lime-silica glasses that are clear or are bulk or surface coloured are preferred. More preferred, these are extra-clear soda-lime-silica glasses. The term extra-clear denotes a glass containing at most 0.020% by weight of the glass of total Fe expressed as Fe₂O₃ and preferably more than 0.015% by weight. Because of its low porosity, the glass has the advantage of assuring the best protection against any form of contamination of a photonic device comprising the transparent substrate according to the invention. For reasons of cost, the refractive index of the glass, n_{support,} preferably has a value in the range of between 1.4 and 1.6. More preferred, the refractive index of the glass has a value equal to 1.5. nₛᵤₚₚₒᵣₜ represents the refractive index of the support at a wavelength of 550 nm.

In a particular embodiment the transparent substrate according to the invention is such that the support has a refractive index in the range of between 1.4 and 1.6 at a wavelength of 550 nm and that the electrode is such that the optical thickness of the coating having properties for improving light transmission, T_{D1} and the geometric thickness of the metal conduction layer, T_{ME}, are linked by the equation:

T_{ME}=T_{ME}_{_{—}}ₒ+[B*sin(π*T_{D1}/T_{D1}_{_{—}}ₒ)](nₛᵤₚₚₒᵣₜ)³

where T_{ME}_{_{—}}ₒ, B and T_{D1}_{_{—}}ₒ are constants with T_{ME}_{_{—}}ₒ having a value in the range of 10.0 to 25.0 nm, preferably 10.0 to 23.0 nm, B having a value in the range of 10.0 to 16.5 nm and T_{D1}_{_{—}}ₒ having a value in the range of 23.9*n_{D1} to 28.3*n_{D1} nm, with n_{D1} representing the refractive index of the coating for improving the light transmission at a wavelength of 550 nm and nₛᵤₚₚₒᵣₜ represents the refractive index of the support at a wavelength of 550 nm. Preferably, constants T_{ME}_{_{—}}ₒ, B and T_{D1}_{_{—}}ₒ are such that T_{ME}_{_{—}}ₒ has a value in the range of 10.0 to 23.0 nm, preferably 10.0 to 22.5 nm, more preferred 11.5 to 22.5 nm, B has a value in the range of 11.5 to 15.0 and T_{D1}_{_{—}}ₒ has a value in the range of 24.8*n_{D1} to 27.3*n_{D1} nm. More preferred, constants T_{ME}_{_{—}}ₒ, B and T_{D1}_{_{—}}ₒ are such that T_{ME}_{_{—}}ₒ has a value in the range of 10.0 to 23.0 nm, preferably 10.0 to 22.5 nm, more preferred 11.5 to 22.5 nm, B has a value in the range of 12.0 to 15.0 and T_{D1}_{_{—}}ₒ has a value in the range of 24.8*n_{D1} to 27.3n_{D1} nm.

In a particular embodiment the transparent substrate according to the invention is such that the support has a refractive index equal to 1.5 at a wavelength of 550 nm and that the electrode is such that the optical thickness of the coating having properties for improving light transmission, T_{D1} and the geometric thickness of the metal conduction layer, T_{ME}, are linked by the equation:

T_{ME}=T_{ME}_{_{—}}ₒ+[B*sin(π*T_{D1}/T_{D1}_{_{—}}ₒ)]/(nₛᵤₚₚₒᵣₜ)³

where T_{ME}_{_{—}}ₒ, B and T_{D1}_{_{—}}ₒ are constants with T_{ME}_{_{—}}ₒ having a value in the range of 10.0 to 25.0 nm, preferably 10.0 to 23.0 nm, B having a value in the range of 10.0 to 16.5 nm and T_{D1}_{_{—}}ₒ having a value in the range of 23.9*n_{D1} to 27.3*n_{D1} nm, with n_{D1} representing the refractive index of the coating for improving the light transmission at a wavelength of 550 nm and nₛᵤₚₚₒᵣₜ represents the refractive index of the support at a wavelength of 550 nm. Preferably, constants T_{ME}_{_{—}}ₒ, B and T_{D1}_{_{—}}ₒ are such that T_{ME}_{_{—}}ₒ has a value in the range of 10.0 to 23.0 nm, preferably 10.0 to 22.5 nm, more preferred 11.5 to 22.5 nm, B has a value in the range of 11.5 to 15.0 and T_{D1}_{_{—}}ₒ has a value in the range of 24.8*n_{D1} to 27.3*n_{D1} nm. More preferred, constants T_{ME}_{_{—}}ₒ, B and T_{D1}_{_{—}}ₒ are such that T_{ME}_{_{—}}ₒ has a value in the range of 10.0 to 23.0 nm, preferably 10.0 to 22.5 nm, more preferred 11.5 to 22.5 nm, B has a value in the range of 12.0 to 15.0 and T_{D1}_{_{—}}ₒ has a value in the range of 24.8*n_{D1} to 27.3*n_{D1} nm.

According to a particular example of the previous embodiment, the transparent substrate according to the invention is such that the geometric thickness of the metal conduction layer is at least equal to 6.0 nm, preferably at least equal to 8.0 nm, more preferred at least equal to 10.0 nm and at most equal to 22.0 nm, preferably at most equal to 20.0 nm, more preferred at most equal to 18.0 nm and wherein the geometric thickness of the coating for improving light transmission is at least equal to 50.0 nm, preferably at least equal to 60.0 nm and at most equal to 130.0 nm, preferably at most equal to 110.0 nm, more preferred at most equal to 90.0 nm.

In a particular embodiment the transparent substrate according to the invention is such that it comprises a support having a refractive index value in the range of 1.4 to 1.6 and is such that the geometric thickness of the metal conduction layer is at least equal to 16.0 nm, preferably at least equal to 18.0 nm, more preferred at least equal to 20.0 nm and at most equal to 29.0 nm, preferably at most equal to 27.0 nm, more preferred at most equal to 25.0 nm and wherein the geometric thickness of the coating for improving light transmission is at least equal to 20.0 nm and at most equal to 40.0 nm. Surprisingly, the use of a thick metal conduction layer combined with an optimised thickness of the coating for improving light transmission allows photonic systems, more particularly OLEDs, to be obtained that have a high luminance as well as incorporating a substrate, in which the electrode has a lower surface resistance expressed in Ω/□.

In another particular embodiment the transparent substrate according to the invention is such that the electrode has a coating for improving light transmission comprising at least one additional crystallisation layer, wherein, in relation to the support, said crystallisation layer is the layer furthest removed from the lamination structure forming said coating.

In a preferred embodiment the substrate according to the invention is such that the refractive index of the material forming the coating for improving light transmission (n_{D1}) is higher than the refractive index of the support (nₛᵤₚₚₒᵣₜ) (n_{D1}>nₛᵤₚₚₒᵣₜ), preferably n_{D1}>1.2 nₛᵤₚₚₒᵣₜ, more preferred n_{D1}>1.3 nₛᵤₚₚₒᵣₜ, most preferred n_{D1}>1.5 nₛᵤₚₚₒᵣₜ. The refractive index of the material forming the coating (n_{D1}) has a value ranging from 1.5 to 2.4, preferably ranging from 2.0 to 2.4, more preferred ranging from 2.1 to 2.4 at a wavelength of 550 nm. When the coating for improving the light transmission is formed from several layers, n_{D1} is given by the equation:

$${n}_{D 1} - \frac{{\sum }_{x = 1}^{m} {n}_{x} \times {1}_{x}}{{1}_{coating}}$$

where m represents the layer number in the coating, nₓ represents the refractive index of the material forming the x-th layer starting from the support, 1ₓ represents the geometric thickness of the x-th layer, 1_{D1} represents the geometric thickness of the coating. The use of a material with a higher refractive index allows a higher amount of emitted or transmitted light to be obtained. The advantage provided is all the more significant as the difference between the refractive index of the coating for improving the light transmission and the refractive index of the support is substantial.

The material forming at least one layer of the coating for improving light transmission comprises at least one dielectric compound and/or at least one electrically conductive compound. The term “dielectric compound” is understood to mean at least one compound selected from the following:

the oxides of at least one element selected from Y, Ti, Zr, Hf, V, Nb, Ta, Cr, Mo, W, Ni, Zn, Al, Ga, In, Si, Ge, Sn, Sb, Bi as well as a mixture of at least two thereof;

nitrides of at least one element selected from boron, aluminium, silicon, germanium as well as a mixture thereof;

silicon oxynitride, aluminium oxynitride;

silicon oxycarbide.

If present, the dielectric compound preferably comprises an yttrium oxide, a titanium oxide, a zirconium oxide, a hafnium oxide, a niobium oxide, a tantalum oxide, a zinc oxide, a tin oxide, an aluminium oxide, an aluminium nitride, a silicon nitride and/or a silicon oxycarbide.

The term “conductive” is understood to relate to a compound chosen from the following:

oxides under-stoichiometric in oxygen and oxides doped with at least one element selected from Ti, Zr, Hf, V, Nb, Ta, Cr, Mo, W, Zn, Al, Ga, In, Si, Ge, Sn, Sb, Bi as well as a mixture of at least two thereof;

nitrides doped with at least one element selected from boron, aluminium, silicon, germanium as well as a mixture thereof;

doped Si oxycarbide;

the doping agents preferably comprise at least one of the elements chosen from Al, Ga, In, Sn, P, Sb, F. In the case of silicon oxynitride the doping agents comprise B, Al and/or Ga.

The conductive compound preferably comprises at least ITO and/or doped Sn oxide, wherein the doping agent is at least one element chosen from F and Sb, and/or doped Zn oxide, wherein the doping agent is at least one element chosen from Al, Ga, Sn, Ti. According to a preferred embodiment, the inorganic chemical compound comprises at least ZnOₓ (where x≦1) and/or ZnₓSn_{y}O_{z} (where x+y≧3 and z≧6). ZnₓSn_{y}O_{z} preferably comprises at most 95% by total weight of the metals present in the layer.

The metal conduction layer of the electrode forming a part of the transparent substrate according to the invention mainly assures the electrical conduction of said electrode. It comprises at least one layer composed of a metal or a mixture of metals. The generic term “mixture of metals” denotes the combinations of at least two metals in the form of an alloy or doping of at least one metal by at least one other metal, wherein the metal and/or the mixture of metals comprises at least one element selected from Pd, Pt, Cu, Ag, Au, Al. The metal and/or mixture of metals preferably comprises at least one element selected from Cu, Ag, Au, Al. More preferred, the metal conduction layer comprises at least Ag in pure form or alloyed to another metal. The other metal preferably comprises at least one element selected from Au, Pd, Al, Cu, Zn, Cd, In, Si, Zr, Mo, Ni, Cr, Mg, Mn, Co, Sn. More preferred, the other metal comprises at least Pd and/or Au, preferably Pd.

According to a particular embodiment, the coating for improving the light transmission of the electrode forming a part of the substrate according to the invention comprises at least one additional crystallisation layer, wherein, in relation to the support, said layer is the layer furthest removed from the lamination structure forming said coating. This layer allows a preferred growth of the metal layer, e.g. of silver, forming the metal conduction layer and thus allows favourable electrical and optical properties of the metal conduction layer to be obtained. It comprises at least one inorganic chemical compound. The inorganic chemical compound forming the crystallisation layer does not necessarily have a high refractive index. The inorganic chemical compound comprises at least ZnOₓ (where x≦1) and/or ZnₓSn_{y}O_{z} (where x+y≧3 and z≧6). ZnₓSn_{y}O_{z} preferably comprises at most 95% by weight of zinc, the percentage by weight of zinc being expressed in relation to the total weight of the metals present in the layer. The crystallisation layer is preferably composed of ZnO. Since the layer having properties for improving light transmission has a generally greater thickness than is usually encountered in the field of multilayer conductive coatings (e.g. low emission type coating), the thickness of the crystallisation layer must be adapted or increased to provide a metal conduction layer with good conduction and very low absorption.

According to a particular embodiment, the geometric thickness of the crystallisation layer is at least equal to 7% of the total geometric thickness of the coating for improving light transmission and preferably 11%, more preferred 14%. For example, in the case of a coating for improving light transmission comprising a layer for improving light transmission and a crystallisation layer, the geometric thickness of the layer for improving light transmission must be reduced if the geometric thickness of the crystallisation layer is increased in order to comply with the relation between the geometric thickness of the metal conduction layer and the optical thickness of the coating for improving light transmission.

According to a particular embodiment, the crystallisation layer is merged with at least one layer for improving light transmission forming the coating for improving light transmission.

According to a particular embodiment, the coating for improving light transmission comprises at least one additional barrier layer, wherein, in relation to the support, said barrier layer is the layer closest to the lamination structure forming said coating. This layer in particular allows the electrode to be protected from any contamination by the migration of alkaline substances coming from the support, e.g. made of soda-lime-silica glass, and thus enables the service life of the electrode to be extended. The barrier layer comprises at least one compound selected from the following:

titanium oxide, zirconium oxide, aluminium oxide, yttrium oxide as well as a mixture of at least two thereof;

mixed oxide of zinc-tin, zinc-aluminium, zinc-titanium, zinc-indium, tin-indium;

silicon nitride, silicon oxynitride, silicon oxycarbide, silicon oxycarbonitride, aluminium nitride, aluminium oxynitride as well as a mixture of at least two thereof;

wherein this barrier layer is possibly doped or alloyed with tin.

According to a particular embodiment, the barrier layer is merged with at least one layer for improving light transmission forming the coating for improving light transmission.

According to a preferred embodiment of the barrier and crystallisation layers, at least one of these two additional layers is merged with at least one layer for improving light transmission forming the coating for improving light transmission.

In a particular embodiment the transparent substrate according to the invention is such that the electrode partly forming it comprises a thin layer for standardising the surface electrical properties located, in relation to the support, at the top of the multilayer lamination forming said electrode. The main function of the thin layer for standardising the surface electrical properties is to allow a uniform transfer of charge to be obtained over the entire surface of the electrode. This uniform transfer is indicated by a balanced flux of emitted or converted light at every point of the surface. It also enables the service life of the photonic devices to be increased, since this transfer is the same at each point, thus eliminating any possible hot spots. The standardisation layer has a geometric thickness of at least 0.5 nm, preferably of at least 1.0 nm. The standardisation layer has a geometric thickness of at most 6.0 nm, preferably at most 2.5 nm, more preferred at most 2.0 nm. It is more preferred that the standardisation layer is equal to 1.5 nm. The standardisation layer comprises at least one layer composed of at least one inorganic material selected from a metal, a nitride, an oxide, a carbide, an oxynitride, an oxycarbide, a carbonitride, an oxycarbonitride.

According to a first particular practical example of the previous embodiment, the inorganic material of the standardisation layer is composed of a single metal or a mixture of metals. The generic term “mixture of metals” denotes the combinations of at least two metals in the form of alloy or doping of at least one metal by at least one other metal. The standardisation layer is composed of at least one element selected from Li, Na, K, Be, Mg, Ca, Ba, Sc, Y, Ti, Zr, Hf, Ce, V, Nb, Ta, Cr, Mo, W, Mn, Fe, Ru, Co, Rh, Ir, Ni, Pd, Pt, Cu, Ag, Au, Zn, B, Al, Ga, In, Tl, C, Si, Ge, Sn, Pb. The metal and/or mixture of metals comprises at least one element selected from Li, Na, K, Mg, Ca, Ti, Zr, Hf, V, Nb, Ta, Cr, Mo, W, Mn, Co, Ni, Pd, Pt, Cu, Ag, Au, Zn, Cd, Al, Si, C. It is more preferred that the metal or the mixture of metals comprises at least one element selected from C, Ti, Zr, Hf, V, Nb, Ta, Ni, Cr, Al, Zn. The mixture of metals preferably comprises Ni—Cr and/or Zn doped with Al. The advantage provided by this particular example is that it allows a better possible compromise to be reached between the electrical properties resulting from the effect of the layer for standardising surface electrical properties, on the one hand, and the optical properties obtained as a result of the improvement coating, on the other. The use of a standardisation layer that has the lowest possible thickness is a basic requirement. In fact, the influence of this layer on the amount of light emitted or converted by the photonic device is all the less when its thickness is low. Therefore, if metallic, this standardisation layer is distinguished from the conduction layer by its lower thickness, since this thickness is insufficient to assure conductivity. It is therefore preferred that the standardisation layer has a geometric thickness of 5.0 nm at most, if it is metallic, i.e. composed of a single metal or a mixture of metals.

According to a second particular embodiment, the inorganic material of the standardisation layer is present in the form of at least one chemical compound selected from carbides, carbonitrides, oxynitrides, oxycarbides, oxycarbonitrides as well as mixtures of at least two thereof. The oxynitrides, oxycarbides, oxycarbonitrides of the standardisation layer can be in non-stoichiometric, preferably under-stoichiometric, form in relation to oxygen. The carbides are carbides of at least one element selected from Be, Mg, Ca, Ba, Sc, Y, Ti, Zr, Hf, Ce, V, Nb, Ta, Cr, Mo, W, Mn, Fe, Co, Rh, Ir, Ni, Pd, Pt, Cu, Au, Zn, Cd, B, Al, Si, Ge, Sn, Pb, preferably at least one element selected from Ti, Zr, Hf, V, Nb, Ta, Cr, Mo, W, Mn, Co, Ni, Pd, Pt, Cu, Au, Zn, Cd, Al, Si, more preferred at least one element selected from Ti, Zr, Hf, V, Nb, Ta, Ni, Cr, Zn, Al. The carbonitrides are carbonitrides of at least one element selected from Be, Sc, Y, Ti, Zr, Hf, V, Nb, Cr, Mo, W, Fe, Co, Zn, B, Al, Si, preferably of at least one element selected from Ti, Zr, Hf, V, Nb, Ta, Cr, Mo, W, Co, Zn, Al, Si, more preferred of at least one element selected from Ti, Zr, Hf, V, Nb, Ta, Cr, Zn, Al. The oxynitrides are oxynitrides of at least one element selected from Be, Mg, Ca, Sr, Sc, Y, Ti, Zr, Hf, V, Nb, Ta, Cr, Mo, W, Mn, Fe, Co, Rh, Ir, Ni, Cu, Au, Zn, B, Al, Ga, In, Si, Ge, preferably of at least one element selected from Ti, Zr, Hf, V, Nb, Ta, Cr, Mo, W, Mn, Co, Ni, Cu, Au, Zn, Al, Si, more preferred of at least one element selected from Ti, Zr, Hf, V, Nb, Ta, Cr, Zn, Al. The oxycarbides are oxycarbides of at least one element selected from Be, Mg, Ca, Sr, Sc, Y, Ti, Zr, Hf, V, Nb, Cr, Mo, W, Mn, Fe, Ni, Zn, Si, Ge, preferably of at least one element selected from Ti, Zr, Hf, V, Nb, Cr, Mo, W, Mn, Ni, Zn, Al, Si, more preferred of at least one element selected from Ti, Zr, Hf, V, Nb, Cr, Zn, Al. The oxycarbonitrides are oxycarbonitrides of at least one element selected from Be, Ti, Zr, Hf, V, Nb, Cr, Mo, W, Mn, Zn, B, Al, Si, Ge, preferably of at least one element selected from Ti, Zr, Hf, V, Nb, Cr, Mo, W, Mn, Zn, Al, Sn, more preferred of at least one element selected from Ti, Zr, Hf, V, Nb, Cr, Zn, Al. The carbides, carbonitrides, oxynitrides, oxycarbides, oxycarbonitrides of the layer for standardising surface electrical properties possibly comprise at least one doping element. In a preferred embodiment, the thin standardisation layer comprises at least one oxynitride composed of at least one element selected from Ti, Zr, Cr, Mo, W, Mn, Co, Ni, Cu, Au, Zn, Al, Si. More preferred the thin layer for standardising surface electrical properties comprises at least one oxynitride selected from Ti oxynitride, Zr oxynitride, Ni oxynitride, NiCr oxynitride.

According to a third particular embodiment, the inorganic material of the standardisation layer is present in the form of at least one metal nitride of at least one element selected from Be, Mg, Ca, Sr, Ba, Sc, Y, Ti, Zr, Hf, V, Nb, Ta, Cr, Mo, W, Mn, Fe, Ru, Os, Co, Rh, Ir, Ni, Pd, Pt, Cu, Ag, Au, Zn, Cd, B, Al, Ga, In, Si, Ge, Sn. Preferably, the standardisation layer comprises at least one nitride of an element selected from Ti, Zr, Hf, V, Nb, Ta, Cr, Mo, W, Mn, Co, Ni, Pd, Pt, Cu, Ag, Au, Zn, Cd, Al, Si. More preferred, the nitride comprises at least one element selected from Ti, Zr, Hf, V, Nb, Ta, Ni, Cr, Al, Zn. More preferred, the thin layer for standardising surface electrical properties comprises at least Ti nitride, Zr nitride, Ni nitride, NiCr nitride.

According to a fourth particular embodiment, the inorganic material of the standardisation layer is present in the form of at least one metal oxide of at least one element selected from Be, Mg, Ca, Sr, Ba, Sc, Y, Ti, Zr, Hf, V, Nb, Ta, Cr, Mo, W, Mn, Fe, Ru, Os, Co, Rh, Ir, Ni, Pd, Pt, Cu, Ag, Au, Zn, Cd, B, Al, Ga, In, Si, Ge, Sn, Pb. Preferably, the standardisation layer comprises at least one oxide of an element selected from Ti, Zr, Hf, V, Nb, Ta, Cr, Mo, W, Mn, Co, Ni, Pd, Pt, Cu, Ag, Au, Zn, Cd, Al, In, Si, Sn. More preferred, the oxide comprises at least one element selected from Ti, Zr, Hf, V, Nb, Ta, Ni, Cu, Cr, Al, In, Sn, Zn. The oxide of the standardisation layer can be a under-stoichiometric oxide in oxygen. The oxide possibly comprises at least one doping element. Preferably, the doping element is selected from at least one of the element chosen from Al, Ga, In, Sn, Sb, F, Ag. More preferred, the thin layer for standardising surface electrical properties comprises at least Ti oxide and/or Zr oxide and/or Ni oxide and/or NiCr oxide and/or ITO and/or doped Cu oxide, wherein the doping agent is Ag, and/or doped Sn oxide, wherein the doping agent is at least one element selected from F and Sb, and/or doped Zn oxide, wherein the doping agent is at least one element selected from Al, Ga, Sn, Ti.

In a particular embodiment the transparent substrate according to the invention is such that the electrode partly forming it comprises at least one additional insertion layer located between the metal conduction layer and the thin standardisation layer. The layer inserted between the metal conduction layer and the standardisation layer comprises at least one layer composed of at least one dielectric compound and/or at least one electrically conductive compound. Preferably, the insertion layer comprises at least one layer composed of at least one conductive compound. The function of this insertion layer is to form a part of an optical cavity that enables the metal conduction layer to become transparent. The term “dielectric compound” is understood to mean at least one compound selected from the following:

the oxides of at least one element selected from Y, Ti, Zr, Hf, V, Nb, Ta, Cr, Mo, W, Zn, Al, Ga, In, Si, Ge, Sn, Sb, Bi as well as the mixture of at least two thereof:

the nitrides of at least one element selected from boron, aluminium, silicon, germanium as well as a mixture thereof;

silicon oxynitride, aluminium oxynitride;

a silicon oxycarbide.

If present, the dielectric compound preferably comprises an yttrium oxide, a titanium oxide, a zirconium oxide, a hafnium oxide, a niobium oxide, a tantalum oxide, a zinc oxide, a tin oxide, an aluminium oxide, an aluminium nitride, a silicon nitride and/or a silicon oxycarbide.

The term “conductive” is understood to relate to a compound chosen from the following:

under-stoichiometric oxides in oxygen and oxides doped with at least one element selected from Y, Ti, Zr, Hf, V, Nb, Ta, Cr, Mo, W, Zn, Al, Ga, In, Si, Ge, Sn, Sb, Bi as well as a mixture of at least two thereof;

nitrides doped with at least one element selected from boron, aluminium, silicon, germanium as well as a mixture thereof;

doped Si oxycarbide;

the doping agents preferably comprise at least one of the elements chosen from Al, Ga, In, Sn, P, Sb, F. In the case of silicon oxynitride the doping agents comprise B, Al and/or Ga.

The conductive compound preferably comprises at least ITO and/or doped Sn oxide, wherein the doping agent is at least one element chosen from F and Sb, and/or doped Zn oxide, wherein the doping agent is at least one element chosen from Al, Ga, Sn, Ti. According to a preferred embodiment, the inorganic chemical compound comprises at least ZnOₓ (where x≦1) and/or ZnₓSn_{y}O_{z} (where x+y≦3 and z≧6). ZnₓSn_{y}O_{z} preferably comprises at most 95% by weight of zinc, and the percentage by weight of zinc is expressed in relation to the total weight of the metals present in the layer.

In a particular practical example of the previous embodiment, the transparent substrate according to the invention is such that the geometric thickness of the insertion layer (Eᵢₙ) is such that its ohmic thickness is at most equal to 10¹² ohm, preferably at most equal to 10⁴ ohm, wherein the ohmic thickness is equal to the relation between the resistivity of the material forming the insertion layer (ρ), on the one hand, and the geometric thickness of this same layer (1), on the other; and the geometric thickness of the insertion layer is, moreover, linked to the geometric thickness of the first organic layer of the organic light-emitting device (E_{org}), the term “first organic layer” denoting all the organic layers disposed between the insertion layer and the organic light-emitting layer, by the equation: E_{org}=Eᵢₙ−A, where A is a constant having a value in the range of 5.0 to 75.0 nm, preferably from 20.0 to 60.0 nm, more preferred from 30.0 to 45.0 nm. The inventors have found that the equation E_{org}=Eᵢₙ−A surprisingly allows the geometric thickness of the first organic layer of the organic light-emitting device to be used to optimise the optical parameters (geometric thickness and refractive index) of the insertion layer and therefore to optimise the amount of light transmitted while retaining a thickness of the insertion layer that is compatible with the electrical properties that enable high ignition voltages, i.e. for a first luminance maximum, to be avoided.

In another particular embodiment, the transparent substrate according to the invention is such that the geometric thickness of the insertion layer (Eᵢₙ) is such that its ohmic thickness is at most equal to 10¹² ohm, preferably at most equal to 10⁴ ohm, wherein the ohmic thickness is equal to the relation between the resistivity of the material forming the insertion layer (ρ), on the one hand, and the geometric thickness of this same layer (1), on the other; and the geometric thickness of the insertion layer is, moreover, linked to the geometric thickness of the first organic layer of the organic light-emitting device (E_{org}), the term “first organic layer” denoting all the organic layers disposed between the insertion layer and the organic light-emitting layer, by the equation: E_{org}=Eᵢₙ−C, where C is a constant having a value in the range of 150.0 to 250.0 nm, preferably from 160.0 to 225.0 nm, more preferred from 75.0 to 205.0 nm. The inventors have found that the equation E_{org}=Eᵢₙ−C surprisingly allows the geometric thickness of the first organic layer of the organic light-emitting device to be used to optimise the optical parameters (geometric thickness and refractive index) of the insertion layer and therefore to optimise the amount of light transmitted while retaining a thickness of the insertion layer that is compatible with the electrical properties that enable high ignition voltages, i.e. for a second luminance maximum, to be avoided.

In another particular embodiment of the transparent substrate according to the invention, the metal conduction layer of the electrode comprises at least one sacrificial layer on at least one of its faces. Sacrificial layer is understood to mean a layer that can be fully or partially oxidised or nitrided. This layer allows deterioration of the metal conduction layer, in particular as a result of oxidation or nitridation, to be avoided. Moreover, although it can be located between the metal conduction layer and the crystallisation layer, the presence of this sacrificial layer is compatible with the action of a crystallisation layer. If present, the sacrificial layer comprises at least one compound selected from metals, nitrides, oxides, under-stoichiometric metal oxides in oxygen. Preferably, the metals, nitrides, oxides, under-stoichiometric metal oxides in oxygen comprise at least one element selected from Ti, Zr, Hf, V, Nb, Ta, Cr, Mo, W, Mn, Fe, Co, Ni, Cu, Zn, Al. The sacrificial layer preferably comprises at least Ti, Zr, Ni, Zn, Al. Most preferred, the sacrificial layer comprises at least Ti, TiOₓ (where x≦2), NiCr, NiCrOₓ, TiZrOₓ (TiZrOₓ indicates a titanium oxide layer with 50% by weight of zirconium oxide), ZnAlOₓ (ZnAlOₓ indicates a zinc oxide layer with 2 to 5% by weight of aluminium oxide). According to a particular embodiment in keeping with the above, the thickness of the sacrificial layer has a geometric thickness of at least 0.5 nm. The thickness of the sacrificial layer comprises a thickness of at most 6.0 nm. It is more preferred if the thickness is equal to 2.5 nm. According to a preferred embodiment, a sacrificial layer is deposited on the face of the metal conduction layer furthest removed in relation to the support.

In another particular embodiment the transparent substrate according to the invention is such that the support on which said electrode is deposited comprises at least one functional coating. Said functional coating is preferably located on the face opposite the face on which the electrode according to the invention is deposited. This coating comprises at least one coating selected from an antireflective layer or multilayer lamination structure, a diffusion layer, a non-fogging or anti-soiling layer, an optical filter, in particular a titanium oxide layer, a selective absorbent layer, a micro-lens system such as those described in the article by Lin and Coll., for example. in Optics Express, 2008, vol. 16, no. 15, pp. 11044-11051 or in document US 2003/0020399 A1,page 6.

In a preferred embodiment the transparent substrate according to the invention essentially has the following structure, starting from a clear or extra-clear glass support:

coating for improving light transmission:

layer for improving light transmission made of TiO₂ (merged with the barrier layer)

crystallisation layer made of ZnO or ZnₓSn_{y}O_{z} (where x+y≧3 and z≦6)

metal conduction layer made of Ag, wherein the geometric thickness of the coating having properties for improving light transmission and the geometric thickness of the metal conduction layer are linked by the equation:

T_{ME}=T_{ME}_{_{—}}ₒ+[B*sin(π*T_{D1}/TD₁_{_{—}}ₒ)]/(nₛᵤₚₚₒᵣₜ)³

where T_{ME}_{_{—}}ₒ, B and T_{D1}_{_{—}}ₒ are constants with T_{ME}_{_{—}}ₒ having a value in the range of 10.0 to 25.0 nm, preferably 10.0 to 23.0 nm, B having a value in the range of 10.0 to 16.5 nm and Tₘ. having a value in the range of 23.9*n_{D1} to 28.3*n_{D1} nm, with n_{D1} representing the refractive index of the coating for improving light transmission at a wavelength of 550 nm and nₛᵤₚₚₒᵣₜ represents the refractive index of the support at a wavelength of 550 nm. Preferably, constants T_{ME}_{_{—}}ₒ, B and T_{D1}_{_{—}}ₒ are such that T_{ME}_{_{—}}ₒ has a value in the range of 10.0 to 23.0 nm, preferably 10.0 to 22.5 nm, more preferred 11.5 to 22.5 nm, B has a value in the range of 11.5 to 15.0 and T_{D1}_{_{—}}ₒ has a value in the range of 24.8*n_{D1} to 27.3*n_{D1} nm. More preferred, constants T_{ME}_{_{—}}ₒ, B and T_{D1}_{_{—}}ₒ are such that T_{ME}_{_{—}}ₒ has a value in the range of 10.0 to 23.0 nm, preferably 10.0 to 22.5 nm, more preferred 11.5 to 22.5 nm, B has a value in the range of 12.0 to 15.0 and T_{D1}_{_{—}}ₒ has a value in the range of 24.8*n_{D1} to 27.3*n_{D1} nm

sacrificial layer: geometric thickness 1.0-3.0 nm made of Ti

insertion layer: geometric thickness 3.0-20.0 nm made of ZnₓSn_{y}O_{z} (where where x+y≧3 and z≦6)

standardisation layer: geometric thickness 0.5-3.0 nm made of X, X nitride, X oxynitride where X: Ti, Zr, Hf, V, Nb, Ta, Ni, Pd, Cr, Mo, Al, Zn, Ni—Cr or Zn doped with Al.

In a preferred embodiment the transparent substrate according to the invention essentially has the following structure, starting from a clear or extra-clear glass support:

coating for improving light transmission:

layer for improving light transmission made of TiO₂ (merged with the barrier layer)

crystallisation layer made of ZnO or ZnₓSn_{y}O_{z} (where x+y≧3 and z≦6)

the geometric thickness of the coating for improving light transmission is at least equal to 50.0 nm, preferably at least equal to 60.0 nm, more preferred at least equal to 70.0 nm and at most equal to 100 nm, preferably at most equal to 90.0 nm, more preferred at most equal to 80.0 nm

metal conduction layer made of Ag, wherein the geometric thickness of the metal conduction layer is at least equal to 6.0 nm, preferably at least equal to 8.0 nm, more preferred at least equal to 10.0 nm and at most equal to 22.0 nm, preferably at most equal to 20.0 nm, more preferred at most equal to 18.0 nm

sacrificial layer: geometric thickness 1.0-3.0 nm made of Ti

insertion layer: geometric thickness 3.0-20.0 nm made of ZnₓSn_{y}O_{z} (where where x+y≧3 and z≦6)

standardisation layer: geometric thickness 0.5-3.0 nm made of X, X nitride, X oxynitride where X: Ti, Zr, Hf, V, Nb, Ta, Ni, Pd, Cr, Mo, Al, Zn, Ni—Cr or Zn doped with Al.

In a preferred embodiment the transparent substrate according to the invention essentially has the following structure, starting from a clear or extra-clear glass support:

coating for improving light transmission:

layer for improving light transmission made of TiO₂ (merged with the barrier layer)

crystallisation layer made of ZnO or ZnₓSn_{y}O_{z} (where x+y≧3 and z≦6)

the geometric thickness of the coating for improving light transmission is at least equal to 20.0 nm and at most equal to 40.0 nm

metal conduction layer made of Ag, wherein the geometric thickness of the metal conduction layer is at least equal to 16.0 nm, preferably at least equal to 18.0 nm, more preferred at least equal to 20.0 nm and at most equal to 29.0 nm, preferably at most equal to 27.0 nm and most preferred at most equal to 25.0 nm

sacrificial layer: geometric thickness 1.0-3.0 nm made of Ti

insertion layer: geometric thickness 3.0-20.0 nm made of ZnₓSn_{y}O_{z} (where where x+y≧3 and z≦6)

standardisation layer: geometric thickness 0.5-3.0 nm made of X, X nitride, X oxynitride where X: Ti, Zr, Hf, V, Nb, Ta, Ni, Pd, Cr, Mo, Al, Zn, Ni—Cr or Zn doped with Al.

In a particular embodiment the transparent substrate according to the invention is such that the reflection on the support side, rₛᵤₚₚₒᵣₜ, in particular a glass support, has a value at least equal to 28% and at most equal to 49%.

The embodiments of the transparent substrate are not limited to the embodiments outlined above, but can equally be formed by combining two or more thereof.

The second subject of the invention relates to the process for the manufacture of the transparent substrate according to the invention. This substrate comprises a support and an electrode. The process for the manufacture of the transparent substrate according to the invention is a process, in which the standardisation layer and/or a layer assembly comprising the electrode are deposited onto the support. Examples of such processes are cathodic sputtering techniques, possibly using a magnetic field, deposition techniques using plasma, CVD (chemical vapour deposition) and/or PVD (physical vapour deposition) techniques. The deposition process is preferably conducted under vacuum. The term “under vacuum” denotes a pressure lower than or equal to 1.2 Pa. More preferred, the process under vacuum is a magnetron sputtering technique. The process for the manufacture of the transparent substrate comprises continuous processes, in which every layer forming the electrode is deposited immediately after the layer underlying it in the multilayer lamination structure (e.g. deposition of the lamination structure forming the electrode according to the invention onto a support that is a moving ribbon or deposition of the lamination structure onto a support that is a panel). The manufacturing process also comprises discontinuous processes in which a time interval (e.g. in the form of storage) separates the deposition of one layer and the layer underlying it in the lamination structure forming the electrode.

According to a preferred embodiment, the process for the manufacture of the transparent substrate according to the invention is such that it is conducted in two phases as follows:

deposition of the support of the coating having properties for improving light transmission,

deposition of the metal conduction layer directly followed by deposition of the different functional elements forming the photonic system.

According to another preferred embodiment, the process for the manufacture of the transparent substrate according to the invention is such that it is conducted in two phases as follows:

deposition of the support of the coating having properties for improving light transmission through the electrode, the metal conduction layer, the sacrificial layer, the insertion layer,

deposition of the standardisation layer directly followed by deposition of the different functional elements forming the photonic system.

When the standardisation layer or metal conduction layer are deposited at a later stage, the organic portion of the photonic device is deposited immediately after deposition of the standardisation layer or the metal conduction layer, i.e. without the standardisation layer or the metal conduction layer being exposed before deposition of the organic portion of the photonic device. The advantage provided by these processes is that oxidation of the conduction and standardisation layers can be avoided when these are made of metal. According to a particular embodiment, the barrier layer is deposited (e.g. by CVD) onto a glass ribbon. The following layers of the lamination structure, with or without the standardisation layer, are deposited under vacuum onto said ribbon or onto glass panels formed by cutting said ribbon. The panels covered by the barrier layer obtained after cutting are stored, if necessary.

According to a particular practical example, the layer for standardising surface electrical properties based on oxides and/or oxynitrides can be obtained by direct deposition. According to an alternative example, the standardisation layer based on oxides and/or oxynitrides can be obtained by oxidation of the metals and/or the corresponding nitrides (e.g. Ti is oxidised in Ti oxide, Ti nitride is oxidised in Ti oxynitride). This oxidation can occur directly or a long time after deposition of the standardisation layer. The oxidation can be natural (e.g. through interaction with an oxidising compound present during the manufacturing process or during storage of the electrode before complete manufacture of the photonic device) or can result from an aftertreatment operation (e.g. treatment in ozone under ultraviolet light).

According to an alternative practical example, the process comprises an additional step of structuring the surface of the electrode. Structuring of the electrode is different from structuring of the support. This additional step consists of shaping the surface and/or decorating the surface of the electrode. The process of shaping the surface of the electrode comprises at least engraving by laser or etching. The process of decorating the surface comprises at least a masking operation. Masking is the operation in which a portion at least of the surface of the electrode is covered with a protective coating as part of an aftertreatment process, e.g. etching of the uncoated parts.

In a third subject of the invention the transparent substrate according to the present invention is incorporated into a photonic device that emits or collects light. According to a preferred embodiment, the photonic device is an organic light-emitting device comprising at least one transparent substrate according to the invention described above.

According to a variation of the previous embodiment, the organic light-emitting device comprises an OLED system above the substrate according to the invention for the purpose of emitting a quasi-white light. Several methods are possible to produce a quasi-white light: by mixing within a single organic layer compounds that emit red, green and blue light, by laminating three organic layer structures corresponding respectively to the emitter parts of red, green and blue light or two organic layer structures (yellow and blue emission), by juxtaposing three (red, green blue emission) or two (yellow and blue emission) organic layer structures connected to a light diffusion system.

The term “quasi-white light” is understood to mean a light in which, with a perpendicular radiation to the surface of the substrate, the chromatic coordinates at 0° are contained in one of the eight chromaticity quadrilaterals, with contours of the quadrilaterals included. These quadrilaterals are defined in pages 10 to 12 of standard ANSI_NEMA_ANSLG C78.377-2008. These quadrilaterals are shown in Figure A1, part 1 entitled “Graphical representation of the chromaticity specification of SSL products in Table 1, on the CIE (x,y) chromaticity diagram”.

According to a particular embodiment, the organic light-emitting device is integrated into a glazing, a double glazing or a laminated glazing. It is also possible to integrate several organic light-emitting devices, preferably a large number of organic light-emitting devices.

According to another particular embodiment, the organic light-emitting device is enclosed in at least one encapsulation material made of glass and/or plastic. The different embodiments of the organic light-emitting devices can be combined.

Finally, the different organic light-emitting devices have an extensive field of application. The invention concerns in particular possible uses of these organic light-emitting devices in the formation of one or more luminous surfaces. The term “luminous surface” includes, for example, lighting tiles, luminous panels, luminous partitions, work surfaces, glasshouses, flashlights, screen bases, drawer bases, luminous roofs, touch screens, lamps, camera flash systems, luminous bases for display, security lights, shelves.

The transparent substrate according to the invention will now be illustrated on the basis of the following figures. The figures show in a non-restrictive manner some substrate structures, more particularly lamination layer structures, forming the electrode contained in the substrate according to the invention. These figures are purely for illustration purposes and do not constitute a representation of structures to scale. Moreover, the performances of the organic light-emitting devices containing the transparent according to the invention will also be shown in the form of figures.

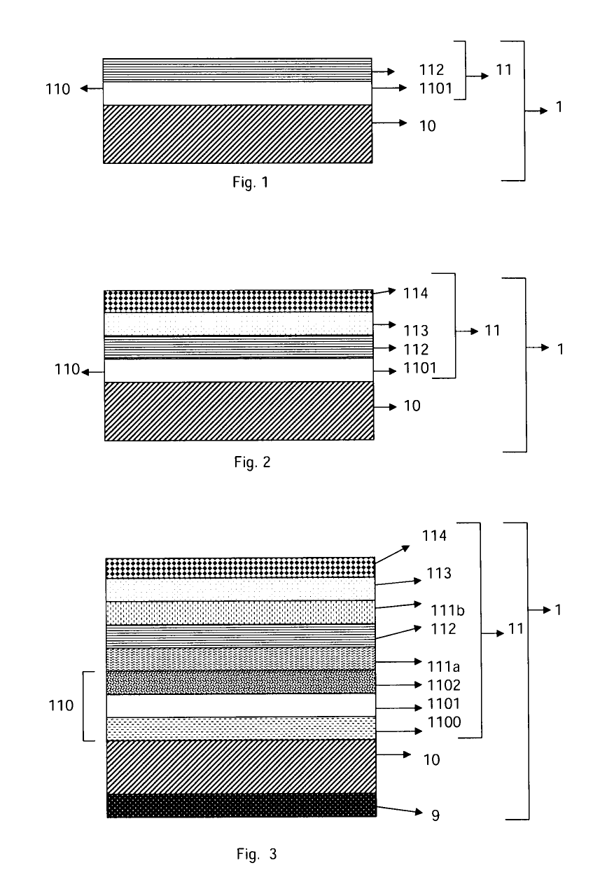

FIG. 1 shows a cross-sectional view of a transparent substrate according to the invention, wherein the substrate comprises an electrode formed from a lamination structure consisting of a minimum number of layers.

FIG. 2 shows a cross-sectional view of a transparent substrate according to the invention in a second embodiment.

FIG. 3 shows a cross-sectional view of a transparent substrate according to the invention, wherein the substrate comprises an electrode formed from a lamination structure consisting of a minimum number of layers and with a different effect.

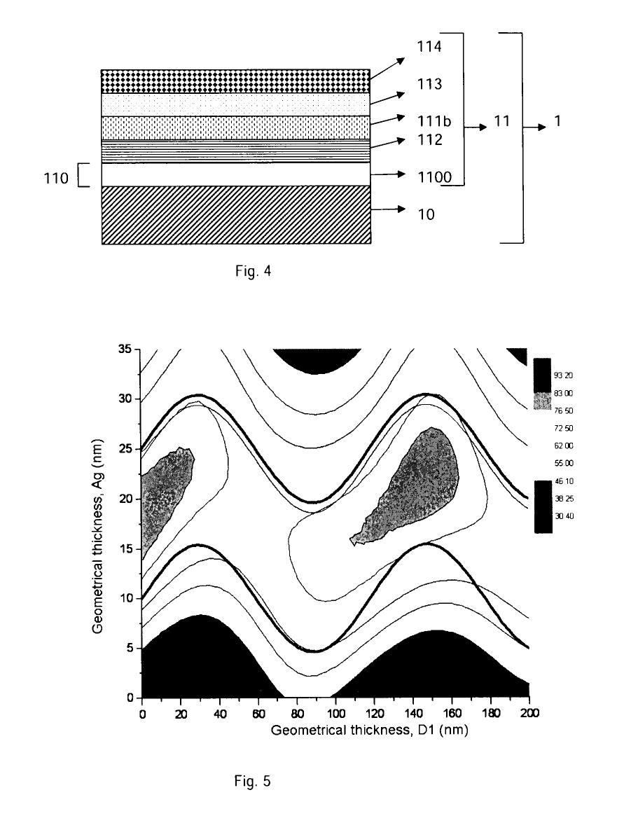

FIG. 4 shows a cross-sectional view of the transparent substrate according to the invention in a preferred embodiment.

FIG. 5 shows the development of the luminance of an organic light-emitting device emitting a quasi-white light and comprising a support with a refractive index of 1.4 at a wavelength equal to 550 nm as a function of the geometric thickness of the coating for improving the light transmission with a refractive index of 2.3 at a wavelength of 550 nm and of the geometric thickness of a metal conduction layer of Ag.

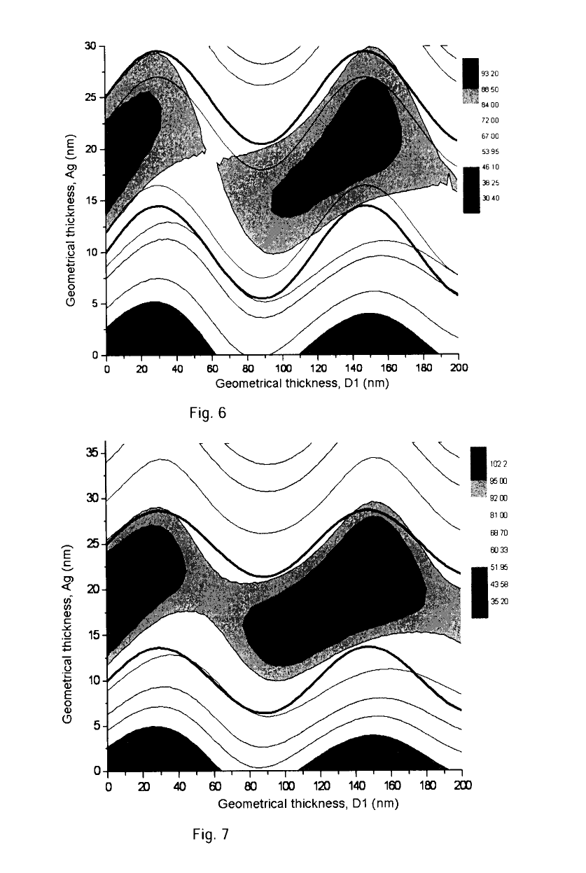

FIG. 6 shows the development of the luminance of an organic light-emitting device emitting a quasi-white light and comprising a support with a refractive index of 1.5 at a wavelength equal to 550 nm as a function of the geometric thickness of the coating for improving the light transmission with a refractive index of 2.3 at a wavelength of 550 nm and of the geometric thickness of a metal conduction layer of Ag.

FIG. 7 shows the development of the luminance of an organic light-emitting device emitting a quasi-white light and comprising a support with a refractive index of 1.6 at a wavelength equal to 550 nm as a function of the geometric thickness of the coating for improving the light transmission with a refractive index of 2.3 at a wavelength of 550 nm and of the geometric thickness of a metal conduction layer of Ag.

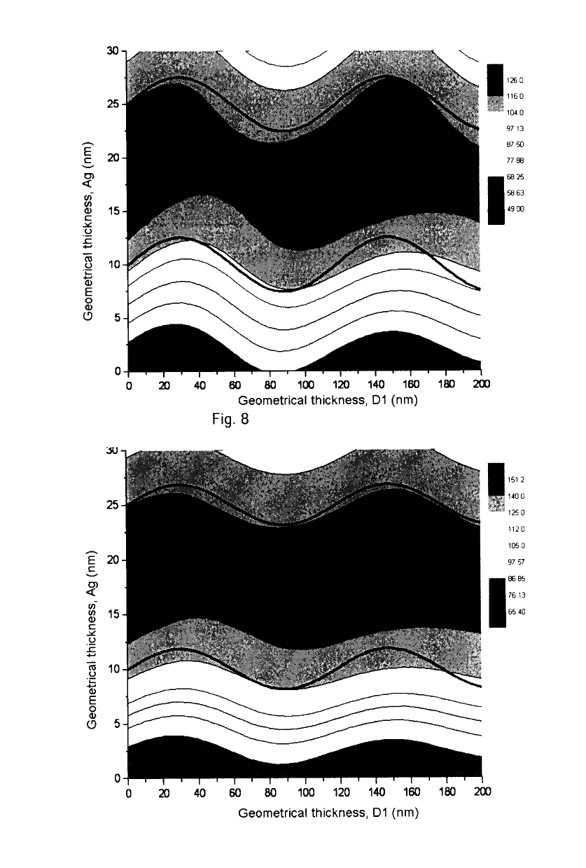

FIG. 8 shows the development of the luminance of an organic light-emitting device emitting a quasi-white light and comprising a support with a refractive index of 1.8 at a wavelength equal to 550 nm as a function of the geometric thickness of the coating for improving the light transmission with a refractive index of 2.3 at a wavelength of 550 nm and of the geometric thickness of a metal conduction layer of Ag.

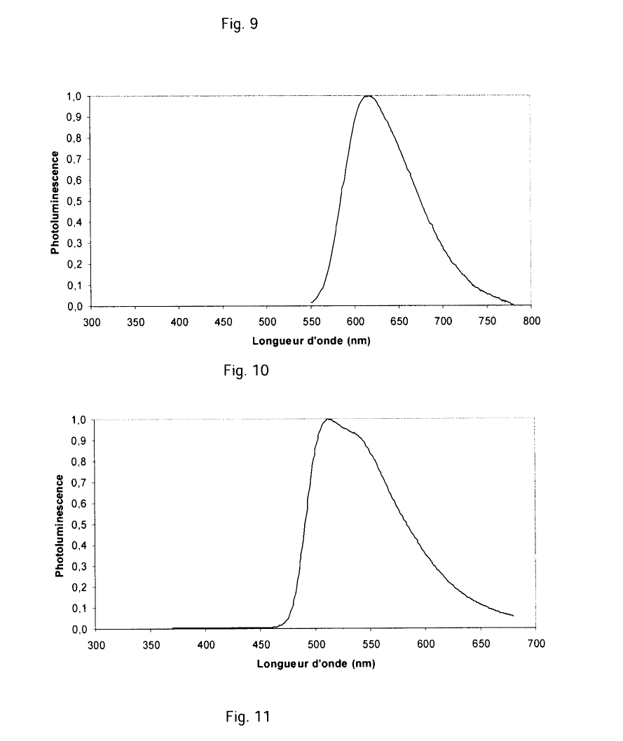

FIG. 9: shows the development of the luminance of an organic light-emitting device emitting a quasi-white light and comprising a support with a refractive index of 2.0 at a wavelength equal to 550 nm as a function of the geometric thickness of the coating for improving the light transmission with a refractive index of 2.3 at a wavelength of 550 nm and of the geometric thickness of a metal conduction layer of Ag.

FIG. 10 shows the photoluminescence as a function of the wavelength spectrum of a monochromic radiation, the main wavelength of which lies in the red light range.

FIG. 11 shows the photoluminescence as a function of the wavelength spectrum of a monochromic radiation, the main wavelength of which lies in the green light range.

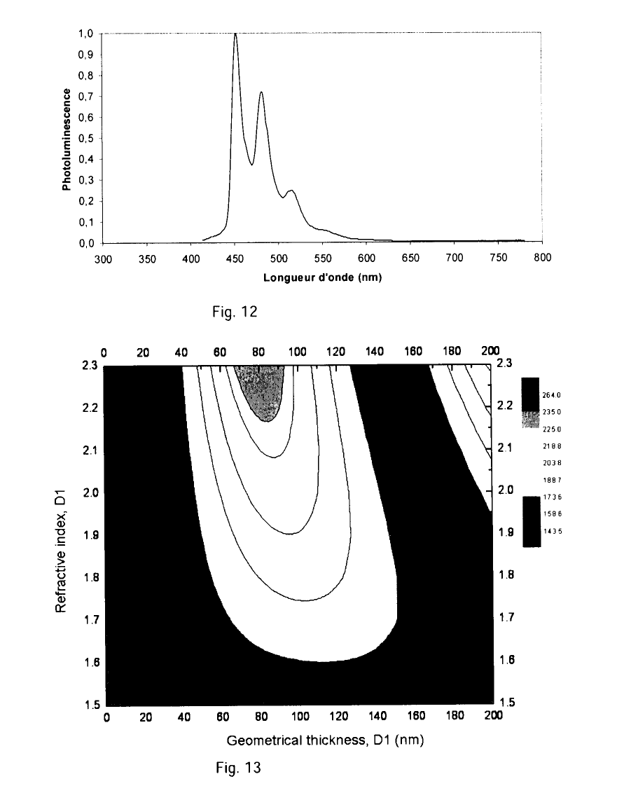

FIG. 12 shows the photoluminescence as a function of the wavelength spectrum of a monochromic radiation, the main wavelength of which lies in the blue light range.

FIG. 13 shows the development of the luminance of the organic light-emitting device as a function of the geometric thickness and the refractive index of the layer for improving light transmission of the electrode according to the invention for a red light, wherein a metal conduction layer of Ag has a geometric thickness equal to 12.5 nm and a support has a refractive index of 1.5.

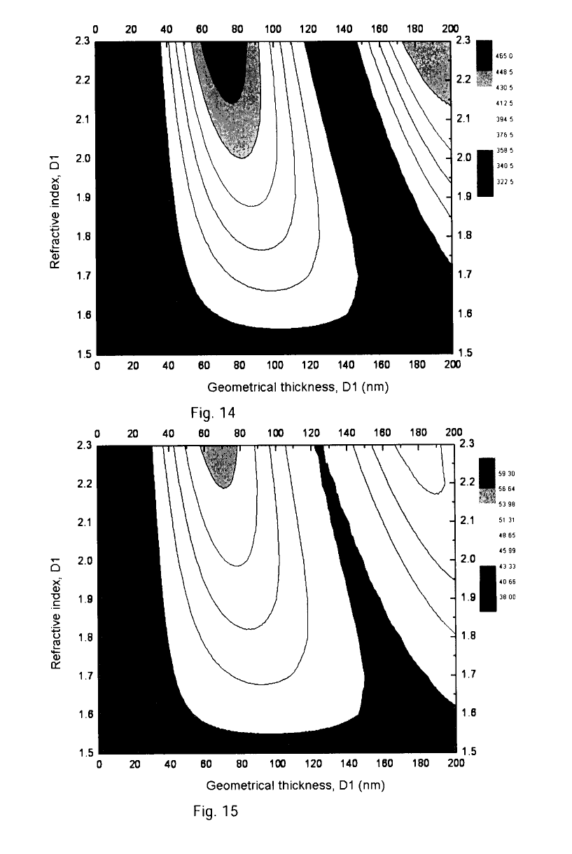

FIG. 14 shows the development of the luminance of the organic light-emitting device as a function of the geometric thickness and the refractive index of the layer for improving light transmission of the electrode according to the invention for a green light, wherein a metal conduction layer of Ag has a geometric thickness equal to 12.5 nm and a support has a refractive index of 1.5.

FIG. 15 shows the development of the luminance of the organic light-emitting device as a function of the geometric thickness and the refractive index of the layer for improving light transmission of the electrode according to the invention for a blue light, wherein a metal conduction layer of Ag has a geometric thickness equal to 12.5 nm and a support has a refractive index of 1.5.

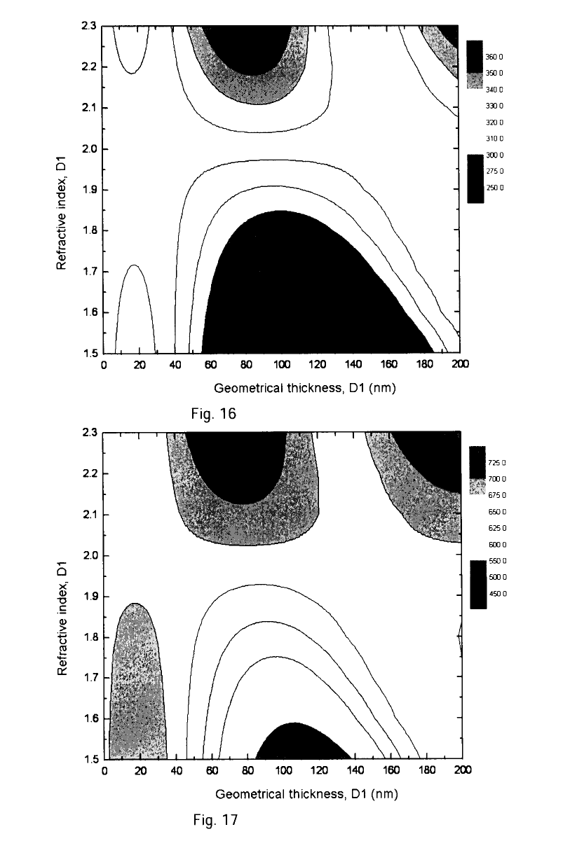

FIG. 16 shows the development of the luminance of the organic light-emitting device as a function of the geometric thickness and the refractive index of the layer for improving transmission of the electrode according to the invention for a red light, wherein a metal conduction layer of Ag has a geometric thickness equal to 12.5 nm and a support has a refractive index of 2.0.

FIG. 17 shows the development of the luminance of the organic light-emitting device as a function of the geometric thickness and the refractive index of the layer for improving light transmission of the electrode according to the invention for a green light, wherein a metal conduction layer of Ag has a geometric thickness equal to 12.5 nm and a support has a refractive index of 2.0.

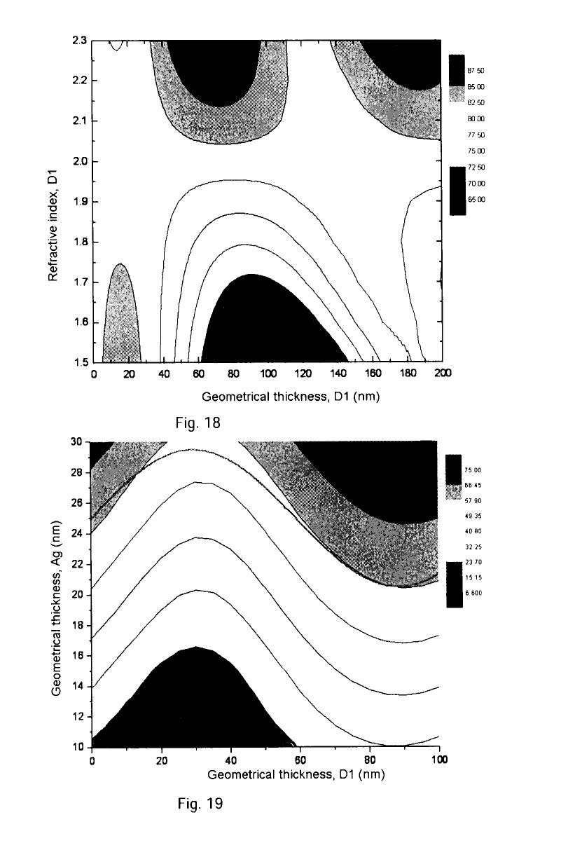

FIG. 18 shows the development of the luminance of the organic light-emitting device as a function of the geometric thickness and the refractive index of the layer for improving light transmission of the electrode according to the invention for a blue light, wherein a metal conduction layer of Ag has a geometric thickness equal to 12.5 nm and a support has a refractive index of 2.0.

FIG. 19 shows the development of the simulated reflection, expressed in D65 at 2° in accordance with European standard EN 410, of a transparent substrate comprising a support with a refractive index equal to 1.5 at a wavelength equal to 550 nm as a function of the geometric thickness of the coating for improving light transmission and of the geometric thickness of the metal conduction layer of Ag, wherein above the conduction layer the substrate also comprises a sacrificial layer of TiOₓ that has a geometric thickness equal to 3.0 nm and an insertion layer of ZnₓSn_{y}O_{z} (where x+y≧3 and z≦6) that has a geometric thickness equal to 14.7 nm, wherein the insertion layer is coated with an organic medium with a refractive index equal to 1.7 at a wavelength of 550 nm.

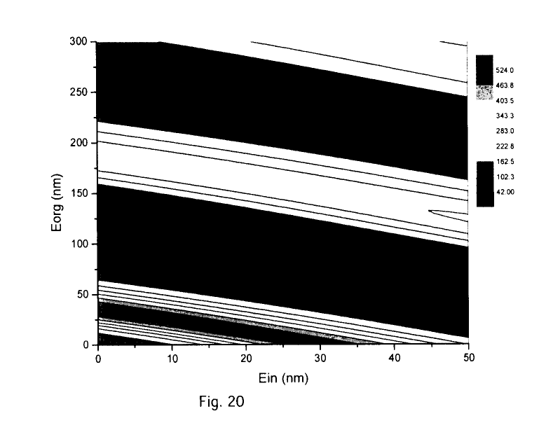

FIG. 20 shows the development of the luminance of the organic light-emitting device incorporating a transparent substrate comprising a support with a refractive index of 1.5 at a wavelength of 550 nm and a metal conduction layer with a geometric thickness of 12.5 nm as a function of the geometric thicknesses of the insertion layer (Eᵢₙ) and the first organic layer of the electrode for a green light.

FIG. 1 shows an example of lamination structure forming a transparent substrate according to the invention. The transparent substrate has the following structure, starting from the support (10):

a coating for improving light transmission (110) comprising a layer for improving light transmission (1101)

a metal conduction layer (112)

FIG. 2 shows an alternative example of the transparent substrate according to the invention. This comprises, in addition to the layers already present in FIG. 1, an insertion layer (113) and a layer for standardising surface electrical properties (114). The transparent substrate has the following structure, starting from the support (10):

a coating for improving light transmission (110) comprising a layer for improving light transmission (1101)

a metal conduction layer (112)

an insertion coating (113)

a standardisation coating (114)

FIG. 3 shows another transparent substrate according to the invention. This comprises, in addition to the layers already present in FIG. 2, an additional barrier layer (1100) and an additional crystallisation layer (1102) belonging to the coating for improving light transmission (110), two sacrificial layers (111a, 111b) and a functional coating (9) on the second face of the support (10). The transparent substrate has the following structure, starting from the second face of the support (10):

a functional coating (9)

a support (10)

a coating for improving light transmission (110) comprising:

a barrier layer (1100)

a layer for improving light transmission (1101)

a crystallisation layer (1102)

a sacrificial layer (111a)

a metal conduction layer (112)

a sacrificial layer (111b)

an insertion layer (113)

a standardisation layer (114)

FIG. 4 shows another example of a transparent substrate according to the invention. The substrate has the following structure, starting from the support (10):

a coating for improving light transmission (110) comprising a layer for improving light transmission (1101)

a metal conduction layer (112)

a sacrificial layer (111b)

an insertion coating (113)

a standardisation coating (114)

FIGS. 5, 6, 7, 8 and 9 show the development of the luminance of an organic light-emitting device emitting a quasi-white light as a function of the geometric thickness of the coating for improving the light transmission (D₁) with a refractive index of 2.3 (n_{D1}) at a wavelength of 550 nm, and of the geometric thickness of a metal conduction layer of Ag and comprising a support with a refractive index equal to 1.4, 1.5, 1.6, 1.8 and 2.0 respectively at a wavelength equal to 550 nm. The structure of the organic light-emitting device comprises the following lamination structure:

support (10) having a geometric thickness equal to 100.0 nm

electrode (11):
coating for improving the light transmission (110),
metal conduction layer made of Ag (112),

the organic portion of the organic light-emitting device is such that it has the following structure:
a hole transporting layer, HTL, having a geometric thickness equal to 25.0 nm,

an electron blocking layer, EBL, having a geometric thickness equal to 10.0 nm,

an emissive layer emitting a Gaussian spectrum of white light corresponding to illuminant A and having a geometric thickness equal to 16.0 nm,

a hole blocking layer, HBL, having a geometric thickness equal to 10.0 nm,

an electron transporting layer, ETL, having a geometric thickness equal to 43.0 nm.

a counter-electrode made of Al having a thickness equal to 100.0 nm.

Surprisingly, these calculations show that a maximum luminance is obtained for a transparent substrate such that the optical thickness of the coating having properties for improving light transmission (110), T_{D1}, and the geometric thickness of the metal conduction layer (112), T_{ME}, are linked by the following equation:

T_{ME}=T_{ME}_{_{—}}ₒ+[B*sin(π*T_{D1}/T_{D1}_{_{—}}ₒ)]n³ₛᵤₚₚₒᵣₜ

where T_{ME}_{_{—}}ₒ, B and T_{D1}_{_{—}}ₒ are constants with T_{ME}_{_{—}}ₒ having a value in the range of 10.0 to 25.0 nm, B having a value in the range of 10.0 to 16.5 nm and T_{D1}_{_{—}}ₒ having a value in the range of 23.9*n_{D1} to 28.3*n_{D1} nm, with n_{D1} representing the refractive index of the coating for improving the light transmission at a wavelength of ^{550 nm and n}ₛᵤₚₚₒᵣₜ represents the refractive index of the support at a wavelength of 550 nm. The luminance was calculated using the program SETFOS, version 3 (Semiconductive Emissive Thin Film Optics Simulator) from Fluxim. This luminance is expressed as arbitrary unit. The sine curves appearing in the form of thicker lines indicate extreme values in the area selected by the equation T_{ME}=T_{ME}_{_{—}}ₒ+[B* sin(π*T_{D1}/T_{D1}_{_{—}}ₒ)]/(nₛᵤₚₚₒᵣₜ)³. The inventors have found that surprisingly the area selected is not only valid for an organic device emitting quasi-white light but also for any type of colour emitted (e.g. red, green, blue).

The inventors have found that, with the same structure of transparent substrate, the use of a support (10) with a high refractive index enables the amount of light transmitted by the photonic system to be increased. A high refractive index is understood to be a refractive index at least equal to 1.4, preferably at least equal to 1.5, more preferred at least equal to 1.6, most preferred at least equal to 1.7. In fact, as comparison of FIGS. 5 and 9 shows, an increase in the order of 180% in the luminance of the OLED is observed when, with the same structure of transparent substrate, a support with a refractive index equal to 2.0 is used instead of a support with a refractive index equal to 1.4, wherein the refractive index of the support is the refractive index at a wavelength of 550 nm.

FIGS. 10 to 19, more particularly FIGS. 13 to 19, relate to a particular example of a transparent substrate according to the invention that corresponds to a conduction layer of Ag having a geometric thickness equal to 12.5 nm. In these figures, the substrate according to the invention is incorporated into an OLED emitting a red, green or blue colour. The structure of the organic light-emitting device comprises the following lamination structure:

support (10) having a geometric thickness equal to 100.0 nm

electrode (11):

coating for improving the light transmission (110),

metal conduction layer made of Ag (112),

the organic portion of the organic light-emitting device is such that it has the following structure:

a hole transporting layer, HTL, having a geometric thickness equal to 25.0 nm,

an electron blocking layer, EBL, having a geometric thickness equal to 10.0 nm,

an emissive layer causing emission of a spectrum of red, green or blue light, of which the chromatic coordinates are respectively equal to coordinates (0.63, 0.36), (0.24, 0.68) or (0.13, 0.31) in the CIE XYZ 1931 colorimetric diagram, according to which the device is provided for the emission of red, green or blue light, and having a geometric thickness equal to 16.0 nm,

a hole blocking layer, HBL, having a geometric thickness equal to 10.0 nm,

an electron transporting layer, ETL, having a geometric thickness equal to 43.0 nm.

a counter-electrode made of Al having a thickness equal to 100.0 nm.

FIGS. 10, 11 and 12 respectively show the development of the photoluminescence as a function of the wavelength spectra of a monochromic radiation, the main wavelength of which lies in the red, green or blue light range. Main wavelength is understood to mean the wavelength at which the photoluminescence is at its maximum. The term “monochromic” is understood to mean that a single colour is perceived by the eye without this light being monochromatic as such. Photoluminescence is expressed in the form of the relation between the value of the photoluminescence at a wavelength divided by the value of maximum photoluminescence. Therefore, the photoluminescence is a number without unit in the range of between 0 and 1. These figures clearly show that the light emitted by the OLED cannot be simply limited to a single wavelength. FIG. 10 shows that at a wavelength equal to 616 nm, the photoluminescence is at maximum in the case of monochromic radiation, the main wavelength of which lies in the red colour range. FIG. 11 shows that at a wavelength equal to 512 nm, the photoluminescence is at maximum in the case of monochromic radiation, the main wavelength of which lies in the green colour range. FIG. 12 shows that at a wavelength equal to 453 nm, the photoluminescence is at maximum in the case of monochromic radiation, the main wavelength of which lies in the blue colour range.

FIGS. 13, 14 and 15 show the development of the luminance of the organic light-emitting device as a function of the geometric thickness (D₁) and the refractive index of the coating for improving the light transmission (n_{D1}) (110) of the transparent substrate according to the invention, respectively for a red, green and blue light colour, and for a support having a refractive index of 1.5 at a wavelength of 550 nm, wherein the geometric thickness of a metal conduction layer of Ag is equal to 12.5 nm. This calculation was conducted not by taking into account a luminous radiation limited to a single wavelength, but by taking into account the real spectrum of wavelengths, as shown in FIGS. 10, 11 and 12. Surprisingly, these calculations show that a maximum luminance is obtained for a transparent substrate that is such that the optical thickness of the coating having properties for improving light transmission (110), T_{D1}, and the geometric thickness of the metal conduction layer (112), T_{ME}, are linked by the following equation:

T_{ME}=T_{ME}_{_{—}}ₒ+[B*sin(π*T_{D1}/T_{D1}_{_{—}}ₒ)](nₛᵤₚₚₒᵣₜ)³

where T_{ME}_{_{—}}ₒ, B and T_{D1}_{_{—}}ₒ are constants with T_{ME}_{_{—}}ₒ having a value in the range of 10.0 to 25.0 nm, B having a value in the range of 10.0 to 16.5 nm and T_{D1}_{_{—}}ₒ having a value in the range of 23.9*n_{D1} to 28.3*n_{D1} nm, with n_{D1} representing the refractive index of the coating for improving the light transmission at a wavelength of ^{550 nm and n}ₛᵤₚₚₒᵣₜ represents the refractive index of the support at a wavelength of 550 nm. The luminance was calculated using the program SETFOS, version 3 (Semiconductive Emissive Thin Film Optics Simulator) from Fluxim. For the special case outlined above, the transparent substrate having a support with a refractive index equal to 1.5 at a wavelength of 550 nm and a conduction layer of Ag with a geometric thickness equal to 12.5 nm, it is evident on the basis of FIGS. 13, 14, 15, obtained for an OLED emitting a red, green and blue light respectively, that a high luminance is obtained more particularly when the geometric thickness of the coating for improving light transmission is at least equal to 50.0 nm, preferably at least equal to 60.0 nm, more preferred at least equal to 70.0 nm and at most equal to 110.0 nm, preferably at most equal to 100.0 nm, more preferred at most equal to 90.0 nm, most preferred at most equal to 80.0 nm. Moreover, on the basis of FIG. 6, which describes the development of the luminance of an organic light-emitting device emitting a quasi-white light and having a support with a refractive index of 1.5 at a wavelength equal to 550 nm as a function of the geometric thickness of the coating for improving light transmission having a refractive index of 2.3 at a wavelength of 550 nm, and of the geometric thickness of a metal conduction layer made of Ag, it is evident that, for a substrate with a thickness of metal conduction layer of Ag of 12.5 nm, the optimum geometric thickness of the coating for improving light transmission must be in the range of between 50.0 nm and 130.0 nm.

FIGS. 16, 17 and 18 show the development of the luminance of the organic light-emitting device as a function of the geometric thickness (D₁) and the refractive index of the coating for improving the light transmission (n_{D1}) (110) of the transparent substrate according to the invention, respectively for a red, green and blue light colour, and for a support having a refractive index of 2.0 at a wavelength of 550 nm, wherein the geometric thickness of a metal conduction layer of Ag is equal to 12.5 nm. This calculation was conducted not by taking into account a luminous radiation limited to a single wavelength, but by taking into account the real spectrum of wavelengths, as shown in FIGS. 10, 11 and 12. Surprisingly, these calculations also show that a maximum luminance is obtained for a transparent substrate which is such that the optical thickness of the coating having properties for improving light transmission (110), T_{D1}, and the geometric thickness of the metal conduction layer (112), T_{ME}, are linked by the following equation:

T_{ME}=T_{ME}_{_{—}}ₒ+[B*sin(π*T_{D1}/T_{D1}_{_{—}}ₒ)]/(nₛᵤₚₚₒᵣₜ)³

where T_{ME}_{_{—}}ₒ, B and T_{D1}_{_{—}}ₒ are constants with T_{ME}_{_{—}}ₒ having a value in the range of 10.0 to 25.0 nm, B having a value in the range of 10.0 to 16.5 nm and T_{D1}_{_{—}}ₒ having a value in the range of 23.9*n_{D1} to 28.3*n_{D1} nm, with n_{D1} representing the refractive index of the coating for improving the light transmission at a wavelength of 550 nm and nₛᵤₚₚₒᵣₜ represents the refractive index of the support at a wavelength of 550 nm. The luminance was calculated using the program SETFOS, version 3 (Semiconductive Emissive Thin Film Optics Simulator) from Fluxim. For the special case outlined above, it is evident on the basis of FIGS. 16, 17, 18, obtained for an OLED emitting a red, green and blue light respectively, that a high luminance is obtained more particularly when the geometric thickness of the coating for improving light transmission is at least equal to 40.0 nm, preferably at least equal to 50.0 nm, more preferred at least equal to 60.0 nm and at most equal to 110.0 nm, preferably at most equal to 100.0 nm, more preferred at most equal to 90.0 nm. Moreover, on the basis of FIG. 9, which describes the development of the luminance of an organic light-emitting device emitting a quasi-white light and having a support with a refractive index of 2.0 at a wavelength equal to 550 nm as a function of the geometric thickness of the coating for improving light transmission having a refractive index of 2.3 at a wavelength of 550 nm, and of the geometric thickness of a metal conduction layer made of Ag, it is evident that, for a substrate with a thickness of metal conduction layer of Ag of 12.5 nm, the optimum geometric thickness of the coating for improving light transmission must be at least greater than 3.0 nm and at most equal to 200.0 nm.

FIGS. 13 to 18 all show that with the same substrate structure in the case of a fixed refractive index of the support, a more significant luminance is obtained when the refractive index of the coating for improving light transmission (110) is higher than the refractive index of the support (10), particularly when n_{D1}>1.2 nₛᵤₚₚₒᵣₜ, more particularly when n_{D1}>1.3nₛᵤₚₚₒᵣₜ, most particularly when n_{D1}>1.5 nₛᵤₚₚₒᵣₜ. The refractive index of the material forming the coating (n_{D1}) has a value ranging from 1.5 to 2.4, preferably ranging from 2.0 to 2.4, more preferred ranging from 2.1 to 2.4, at a wavelength of 550 nm.

Surprisingly, the inventors have found that the optimum thickness of the improvement coating to obtain a maximum luminance, in other words a high emission level, depends little on the wavelength spectrum of the monochromic radiation (blue, green or red light), as demonstrated in FIGS. 13 to 18. More surprisingly, this optimum lies in the same range of geometric thickness of the improvement coating (110). For example, in the case of a material with a refractive index ranging from 2.0 to 2.3, the geometric thickness of the improvement coating that enables an optimum emission at different wavelengths has a value ranging from 45.0 to 95.0 nm. This range is centred around a geometric thickness value of 70.0 nm. Moreover, respective comparisons of FIGS. 8 and 11 for red light, FIGS. 9 and 12 for green light and FIGS. 10 and 13 for blue light show that the refractive index of the support has little influence on the optimum thickness range of the improvement coating.

The inventors have found that in addition to providing a high emission level, the use of a transparent substrate that is such that the optical thickness of the coating having properties for improving light transmission (110), T_{D1}, and the geometric thickness of the metal conduction layer (112), T_{ME}, are linked by the following equation:

T_{ME}=T_{ME}_{_{—}}ₒ+[B*sin(π*T_{D1}/T_{D1}_{_{—}}ₒ)]/(nₛᵤₚₚₒᵣₜ)³

allows a quasi-white light to be provided when sources of red, blue and green light are used at the same time, as FIGS. 5 to 9 show. More particularly, as FIGS. 13 to 15 show, when the transparent substrate is such that it is formed by a support with a refractive index equal to 1.5 at a wavelength of 550 nm and with a conduction layer of Ag with a geometric thickness equal to 12.5 nm, the inventors have been able to determine that for every material with a refractive index within the range of values from 2.0 to 2.3, the optimum geometric thickness of the improvement coating (110) with a value ranging from 45 to 95 nm surprisingly allows a quasi-white light to be obtained. The quasi-white light is preferably obtained with a geometric thickness ranging from 60.0 to 80.0 nm, more preferred from 65.0 to 75.0 nm. Thus, the simultaneous use of three light sources that emit spectra of colorimetric coordinates (0.63, 0.36) for the red light source, (0.26, 0.68) for the green light source and (0.13, 0.31) for the blue light source allows a quasi-white light to be obtained, i.e. for a coating improving light transmission with a geometric thickness of 70.0 nm and a refractive index of 2.3.

On the basis of FIGS. 5 to 7 the inventors have surprisingly found that two particular areas can be selected in the structures of transparent substrates intended for incorporation into an organic light-emitting device. The first area of selection relates to transparent substrates, wherein the support has a refractive index equal to 1.5 at a wavelength of 550 nm and the geometric thickness of the metal conduction layer is at least equal to 6.0 nm, preferably at least equal to 8.0 nm, more preferred at least equal to 10.0 nm and at most equal to 22.0 nm, preferably at most equal to 20.0 nm, more preferred at most equal to 18.0 nm and wherein the geometric thickness of the coating for improving light transmission is at least equal to 50.0 nm, preferably at least equal to 60.0 nm and at most equal to 130.0 nm, preferably at most equal to 110.0 nm, more preferred at most equal to 90.0 nm. This structure has the triple advantage of using a low-cost soda-lime-silica glass support, of using finer metal conduction layers (e.g. of Ag) combined with greater thicknesses of the coating for improving light transmission, and such thicknesses allow a better protection of the metal conduction layer against possible contamination by the migration of alkaline substances coming from the soda-lime-silica glass support.

The second area of selection concerns transparent substrates with a support with a refractive index value in the range of 1.4 to 1.6, wherein the geometric thickness of the metal conduction layer is at least equal to 16 nm, preferably at least equal to 18 nm, more preferred at least equal to 20 nm and at most equal to 29 nm, preferably at most equal to 27 nm, more preferred at most equal to 25 nm, and wherein the geometric thickness of the coating for improving light transmission is at least equal to 20.0 nm and at most equal to 40.0 nm. This structure has the advantage of using thicker metal conduction layers (e.g. of silver), the use of a thick metal conduction layer enabling better conduction to be achieved.

FIG. 19 shows the development of the simulated reflection, expressed in D65 at 2° in accordance with European standard EN 410, of a transparent substrate comprising a support having a refractive index equal to 1.5 at a wavelength equal to 550 nm as a function of the geometric thickness of the coating for improving light transmission and of the geometric thickness of the metal conduction layer of Ag, wherein above the conduction layer the substrate also comprises a sacrificial layer of TiO. that has a geometric thickness equal to 3.0 nm and an insertion layer of ZnₓSn_{y}O_{z} (where x+y≧3 and z≦6) that has a geometric thickness equal to 14.7 nm, wherein the insertion layer is coated with an organic medium with a refractive index equal to 1.7 at a wavelength of 550 nm. The sine curves appearing in the form of thicker lines indicate extreme values in the area selected by the equation T_{ME}=T_{ME}_{_{—}}ₒ+[B*sin(π*T_{D1}/T_{D1}_{_{—}}ₒ)]/(nₛᵤₚₚₒᵣₜ)³. The inventors have found that surprisingly the area selected does not correspond to the area with minimum reflection, but corresponds to a reflection at least equal to 28% and at most equal to 49%, wherein the reflection is calculated in accordance with standard EN 410.

FIG. 20 shows the development of the luminance of the organic light-emitting device incorporating a transparent substrate comprising a support with a refractive index of 1.5 at a wavelength of 550 nm and a metal conduction layer having a geometric thickness of 12.5 nm as a function of the geometric thicknesses of the insertion layer (Eᵢₙ) and the first organic layer of the electrode (E_{org}) for a green light. This calculation was conducted not by taking into account a luminous radiation limited to a single wavelength, but by taking into account the real spectrum of wavelengths, as shown in FIG. 11. The luminance was also calculated using the program SETFOS, version 3. This luminance is expressed as arbitrary unit. The inventors have surprisingly found that two areas characterised by the luminance maxima were observed:

the first area corresponding to the equation: E_{org}=Eᵢₙ−A, where A is a constant having a value in the range of 5.0 to 75.0 nm, preferably from 20.0 to 60.0 nm, more preferred from 30.0 to 45.0 nm.

the second area corresponding to the equation: E_{org}=Eᵢₙ−C, where C is a constant having a value in the range of 150.0 to 250.0 nm, preferably from 160.0 to 225.0 nm, more preferred from 75.0 to 205.0 nm.

The inventors have found that the equations E_{org}=Eᵢₙ−A or E_{org}=Eᵢₙ−C surprisingly allow the geometric thickness of the first organic layer of the organic light-emitting devices to be used to optimise the optical parameters (geometric thickness and refractive index) of the insertion layer and therefore to optimise the amount of light transmitted while retaining a thickness of the insertion layer that is compatible with the electrical properties that enable high ignition voltages, i.e. respectively for a first and a second luminance maximum, to be avoided.

The transparent substrate according to the invention, its mode of execution as well as the organic light-emitting device containing it will now be characterised on the basis of practical examples described and collated in the following Tables Ib and IIb. These examples are in no way restrictive of the invention.

The organic light-emitting devices that emit a green-coloured monochromic radiation whose performances are shown in Tables Ia to VI have the following organic structure, starting from the substrate (1):

a layer of N,N′-bis(1-naphthyl)-N,N-diphenyl-1,1′-biphenyl-4,4′-diamine, abbreviated to alpha-NPD,

a layer of 1,4,7-triazacyclononane-N,N′,N″-triacetate (abbreviated to TCTA)+tris[2-(2-pyridinyl)phenyl-C,N]iridium, abbreviated to Ir(ppy)₃,

a layer of 4,7-diphenyl-1,10-phenanthroline (abbreviated to BPhen),

a layer of LiF,

an upper reflective electrode composed of at least one metal. According to a preferred embodiment, the metal of the upper reflective electrode consists of at least Ag. According to an alternative embodiment, the metal of the upper reflective electrode consists of at least Al.

Besides the transparent substrate according to the invention, the organic light-emitting devices that emit a quasi-white light whose performances are shown in Table VII have the following structure, starting with the substrate:

a layer of N,N,N′,N″-tetrakis(4-methoxyphenyl)-benzidine (abbreviated to MeO-TPD) doped with 4 mole % of NPD-2

a layer of N,N′-di(naphthalen-1-yl)-N-N′-diphenyl-benzidine (abbreviated to NPB),

a lamination of emission layers formed from 4,4′,4″-tris(N-carbazolyl)-triphenylamine (abbreviated to TCTA) and from 2,2′,2″(1,3,5-benzenetriyl) tris(1-phenyl-1H-benzidimazole) (abbreviated to TBPi) partially doped with iridium-bis-(4,6-difluorophenyl-pyridinato-N,C2)-picolinate (abbreviated to FirPic), tris[2-(2-pyridinyl)phenyl-C,N]iridium (abbreviated to Ir(ppy)3) and iridium (III)bis(2-methyldibenzo[f,h]quinoxaline) (acetylacetonate) (abbreviated to Ir5MDQ)₂ (acac),

a layer of 2,2′,2″(1,3,5-benzenetriyl) tris-(1-phenyl-1H-benzimidazole) (abbreviated to TBPi),

a layer of 4,7-diphenyl-1,10-phenanthroline doped with Cs,

an upper reflective electrode composed of at least one metal. According to a preferred embodiment, the metal of the upper reflective electrode consists of at least Ag. According to an alternative embodiment, the metal of the upper reflective electrode consists of at least Al.

The acronyms used to denote the compounds used are well known to the person skilled in the art. The structure of the organic layers used is described in page 237 in section “Methods Summary” of the article by Reineke et Coll. in Nature, 2009, vol. 459, pp. 234 to 238.

The layers forming the electrode (1) of the examples of transparent substrate (1) according to the invention have been deposited by magnetron sputtering onto a clear glass support (10) with a thickness of 1.60 mm.

The deposition conditions for each of the layers are as follows:

the TiO₂-based layers are deposited using a titanium target at a pressure of 0.5 Pa in an Ar/O₂ atmosphere,

the ZnₓSn_{y}O_{z}-based layers are deposited using a target of ZnSn alloy at a pressure of 0.5 Pa in an Ar/O₂ atmosphere,

the Ag-based layers are deposited using an Ag target at a pressure of 0.5 Pa in an Ar atmosphere,

the Ti-based layers are deposited using a Ti target at a pressure of 0.5 Pa in an Ar atmosphere and can be partially oxidised by the subsequent Ar/O₂ plasma,

the layers for standardising surface electrical properties based on Ti nitride are deposited using a Ti target at a pressure of 0.5 Pa in an 80/20 Ar/N₂ atmosphere.

### EXAMPLES

Table Ia shows three columns with examples of transparent substrates (1) having different types of electrodes (numbers of layers, chemical nature and thickness of layers) as well as the results of measurements of electrical and optical performance obtained by means of the organic light-emitting device in which these substrates are incorporated. The general structure of the organic light-emitting device has been described above (p. 39, I. 26 to p. 40, I. 8). Examples 1R, 2R and 3R are three examples not in conformity with the invention. Example 1R is a transparent substrate comprising an electrode of ITO. Example 2R is a transparent substrate comprising an electrode based on an architectural low-emission lamination structure having a conduction layer of Ag. Example 2R is a transparent substrate that is not optimised for an OLED, since the electrode does not have a standardisation layer (114) and the thickness of the improvement coating (110) has not been optimised and therefore lies outside the optical thickness range complying with equation:

T_{ME}=T_{ME}_{_{—}}ₒ+[B*sin(π*T_{D1}/T_{D1}_{_{—}}ₒ)]/(nₛᵤₚₚₒᵣₜ)³

Example 3R is a transparent substrate comprising an electrode based on an architectural low-emission lamination structure having a conduction layer of Ag. Example 3R is a transparent substrate comprising an electrode that is not optimised for an OLED having a standardisation layer (114), wherein the thickness of the improvement coating (110) has not been optimised and therefore lies outside the optical thickness range complying with equation:

T_{ME}=T_{ME}_{_{—}}ₒ+[B*sin(π*T_{D1}/T_{D1}_{_{—}}ₒ)](nₛᵤₚₚₒᵣₜ)³

In examples 2R and 3R, the improvement coating (114) has a barrier layer (1100), which is merged with a layer for improving light transmission (1101) and this layer is covered by a crystallisation layer (1102). Moreover, the crystallisation (1102) and insertion (113) layers are of the same nature. These layers are made of ZnₓSn_{y}O_{z} (where x+y≧3 and z≦6), the ZnₓSn_{y}O_{z} preferably comprising at most 95% by weight of zinc, the percentage by weight of zinc being expressed in relation to the total weight of the metals present in the layer.

Table Ib shows 2 columns with examples of transparent substrates (1) having different types of electrodes (numbers of layers, chemical nature and thickness of layers) as well as the results of measurements of electrical and optical performance obtained by means of the organic light-emitting device in which these substrates are incorporated. The general structure of the organic light-emitting device has been described above (p. 39, I. 26 to p. 40, I. 8). Examples 4 and 5 illustrate substrates in conformity with the invention as well as the electrical and optical performance of the organic light-emitting device in which these are incorporated. In these examples, the improvement coating (110) comprises a barrier layer (1100), which is merged with an improvement layer (1101) and this layer is covered by a crystallisation layer (1102). Moreover, the crystallisation (1102) and insertion (113) layers are of the same nature. These layers are made of ZnₓSn_{y}O_{z} (where x+y≧3 and z≦6), the ZnₓSn_{y}O_{z} preferably comprising at most 95% by weight of zinc, the percentage by weight of zinc being expressed in relation to the total weight of the metals present in the layer.

Comparison of Tables Ia and lb clearly shows the advantages provided by the transparent substrate according to the invention in terms of electrical and optical performance illustrated by examples 4 and 5 of Table Ib. In fact, with respect to electrical performance, in relation to the substrate having an electrode of ITO, example 1R, Table Ia, it has been determined that an equivalent current flux is obtained by applying a voltage reduced to a minimum of 9%. In relation to a transparent substrate with a classic low-emission coating as electrode, example 2R, Table Ia, an equivalent current flux is obtained by applying a voltage reduced to a minimum of 37%. With respect to optical performance, in relation to the substrate having an electrode of ITO, example 1R, Table Ia, it has been determined that an equivalent current flux is obtained by applying voltages to a minimum of 4% lower than the voltages applied to the ITO electrode. Moreover, in relation to a transparent substrate with a classic low-emission coating as electrode, example 2R, Table Ia, an equivalent current flux is obtained by applying voltages reduced to a minimum of 37%. In relation to a substrate having an electrode that is not optimised to an OLED having a standardisation layer (114), wherein the thickness of the improvement coating (110) has not been optimised, example 3R of Table IA, an equivalent light flux is obtained by applying voltages reduced to a minimum of 17%.

TABLE Ia

| | | Examples | | |
|---|---|---|---|---|
| | | 1R | 2R | 3R |
| | | Nature/ | Nature/ | Nature/ |
| | | thickness | thickness | thickness |
| Coating | Layers | (nm) | (nm) | (nm) |
| Improvement | Barrier | — | TiO₂/20.0 | TiO₂/20.0 |
| (110) | (1100) | | | |
| | Improvement | | | |
| | (1101) | | | |
| | Crystallisation | | ZnₓSn_{y}O_{z}/5.0 | ZnₓSn_{y}O_{z}/ |
| | (1102) | | | 5.0 |

| | | | |
|---|---|---|---|
| Conduction layer (112) | ITO/90.0 | Ag/12.5 | Ag/12.5 |
| Sacrificial layer (111b) | — | Ti/2.5 | Ti/2.5 |
| Insertion layer (113) | — | ZnₓSn_{y}O_{z}/14.0 | ZnₓSn_{y}O_{z}/ |
| | | | 7.0 |
| Standardisation layer (114) | — | — | Ti nitride/1.5 |
| Resistance (Ω/□) | 35.00 | 4.00 | 3.78 |
| Electrical performance | | | |
| V at 10 mA/cm² | 3.00 | 4.45 | — |
| V at 100 mA/cm² | 3.90 | 5.60 | — |
| Optical performance | | | |
| V at 1000 cd/m² | 2.70 | 4.10 | 3.15 |
| V at 10000 cd/m² | 3.20 | 5.00 | 3.95 |

The support (10) is a clear glass with a geometric thickness equal to 1.60 mm.

The electrical performance is measured by applied voltages (V) to obtain either a current of 10 mA/cm² or a current of 100 mA/cm². The optical performance is measured by applied voltages (V) to obtain either a light intensity of 1000 cd/m² or 10000 cd/m².

TABLE Ib

| | | Examples | |
|---|---|---|---|
| | | 4 | 5 |
| | | Nature/thickness | Nature/thickness |
| Coating | Layers | (nm) | (nm) |
| Improvement | Barrier | TiO₂/65.0 | TiO₂/65.0 |
| (110) | (1100) | | |
| | Improvement | | |
| | (1101) | | |
| | Crystallisation | ZnₓSn_{y}O_{z}/5.0 | ZnₓSn_{y}O_{z}/5.0 |
| | (1102) | | |

| | | |
|---|---|---|
| Conduction layer (112) | Ag/12.5 | Ag/12.5 |
| Sacrificial layer (111b) | Ti/2.5 | Ti/2.5 |
| Insertion layer (113) | ZnₓSn_{y}O_{z}/7.0 | ZnₓSn_{y}O_{z}/7.0 |
| Standardisation layer (114) | Ti nitride/1.5 | Ti/1.5 |
| Resistance (Ω/□) | 4.09 | 4.00 |
| Electrical performance | | |
| V at 10 mA/cm² | 2.70 | 2.60 |
| V at 100 mA/cm² | 3.55 | 3.45 |
| Optical performance | | |
| V at 1000 cd/m² | 2.60 | 2.55 |
| V at 10000 cd/m² | 2.95 | 2.85 |

The support (10) is a clear glass with a geometric thickness equal to 1.60 mm.

The electrical performance is measured by applied voltages (V) to obtain either a current of 10 mA/cm² or a current of 100 mA/cm². The optical performance is measured by applied voltages (V) to obtain either a light intensity of 1000 cd/m² or 10000 cd/m².

Table IIa shows three columns with examples of the transparent substrate comprising different types of electrodes (numbers of layers, chemical nature and thickness of layers) as well as the results of maximum luminance calculations expressed as arbitrary unit (a.u.) conducted using the program SETFOS version 3 from Fluxim for a monochromic radiation of red, green and blue light in accordance with FIGS. 10, 11 and 12 respectively for an organic light-emitting device incorporating these substrates. The general structure of the organic light-emitting device has been described above (p. 32, I. 8 to p. 33, I. 5). Examples 1R, 2R, 3R and 4R are four examples not in conformity with the invention. Example 1R is a transparent substrate comprising an electrode of ITO, example 2R is a transparent substrate comprising an ITO electrode with a Fabry-Perot micro-cavity based on dielectric materials. Example 3R is a transparent substrate having an electrode based on an architectural low-emission lamination structure having a conduction layer of Ag (112), but not comprising a layer for standardising surface electrical properties (114), wherein the thickness of the improvement coating (10) has not been optimised. Example 4R is a transparent substrate having an electrode based on an architectural low-emission lamination structure having a conduction layer of Ag (112), also comprising a layer for standardising surface electrical properties (114), wherein the thickness of the improvement coating (110) has not been optimised. In examples 3R and 4R, the improvement coating (110) comprises a barrier layer (1100), which is merged with an improvement layer (1101) and this layer is covered by a crystallisation layer (1102). Moreover, the crystallisation (1102) and insertion (113) layers are of the same nature. These layers are made of ZnₓSnp, (where x+y≧3 and z≦6), the ZnₓSn_{y}O_{z} comprising at most 95% by weight of zinc, the percentage by weight of zinc being expressed in relation to the total weight of the metals present in the layer.

Table IIb shows one column with an example of a transparent substrate in conformity with the invention (example 5) and results of maximum luminance calculations expressed as arbitrary unit (a.u.) conducted using the program SETFOS version 3 from Fluxim for a monochromic radiation of red, green and blue light in accordance with FIGS. 10, 11 and 12 respectively for an organic light-emitting device incorporating these substrates. The general structure of the organic light-emitting device has been described above (p. 32, 1. 8 to p. 33, 1. 5). In this example, the improvement coating (110) has an optical thickness complying with equation:

T_{ME}=T_{ME}_{_{—}}ₒ+[B*sin(π*T_{D1}/T_{D1}_{_{—}}ₒ)]/(nₛᵤₚₚₒᵣₜ)³

and this has a barrier layer (1100), which is merged with an improvement layer (1101) and this layer is covered by a crystallisation layer (1102). Moreover, the crystallisation (1102) and insertion (114) layers are of the same nature. These layers are made of ZnₓSn_{y}O_{z} (where x+y≧3 and z≦6), the ZnₓSn_{y}O_{z} preferably comprising at most 95% by weight of zinc, the percentage by weight of zinc being expressed in relation to the total weight of the metals present in the layer.

Comparison between the luminance values obtained in the case of example 5, Table IIb for a transparent substrate according to the invention are clearly higher than the values obtained in the case of examples 1R, 2R, 3R and 4R, Table IIa. This comparison clearly demonstrates the advantages provided by the substrate according to the invention. In fact, in relation to the comparative example showing the best performance (example 3R, Table IIA), example 5 of Table IIb that uses a transparent substrate according to the invention enables an increase in maximum luminance values to be obtained in the order of 47% for green light, in the order of 44% for red light and in the order of 33% for blue light.

TABLE IIa

| | | Examples | | | |
|---|---|---|---|---|---|
| | | 1R | 2R | 3R | 4R |
| | | Nature/ | Nature/ | Nature/ | Nature/ |
| | | thickness | thickness | thickness | thickness |
| Coating | Layers | (nm) | (nm) | (nm) | (nm) |
| Improvement | Barrier | — | TiO₂/246 | TiO₂/20.0 | TiO₂/20.0 |
| (110) | (1100) | | SiO₂/304 | | |
| | Improvement | | TiO₂/246 | | |
| | (1101) | | SiO₂/304 | | |
| | Crystallisation | | TiO₂/246 | ZnₓSn_{y}O_{z}/5.0 | ZnₓSn_{y}O_{z}/5.0 |
| | (1102) | | SiO₂/304 | | |
| | | | TiO₂/246 | | |
| | | | SiO₂/304 | | |

| | | | | |
|---|---|---|---|---|
| Conduction layer (112) | ITO/90.0 | ITO/158.0 | Ag/12.5 | Ag/12.5 |
| Sacrificial layer (111b) | — | — | Ti/2.5 | Ti/2.5 |
| Insertion layer (113) | — | — | ZnₓSn_{y}O_{z}/14.0 | ZnₓSn_{y}O_{z}/14.0 |
| Standardisation layer (114) | — | — | — | Ti nitride/1.5 |
| Resistance (Ω/□) | 35.00 | — | 4.00 | 4.00 |
| Maximum luminance (a.u.) | 240 | 245 | 309 | 302 |
| with green light | | | | |
| Maximum luminance (a.u.) | 105 | 87 | 157 | 153 |
| with red light | | | | |
| Maximum luminance (a.u.) | 31 | 33 | 40 | 39 |
| with blue light | | | | |

The support (10) is a clear glass with a geometric thickness equal to 100 nm.

TABLE IIb

| | | Example |
|---|---|---|
| | | 5 |
| Coating | Layers | Nature/thickness (nm) |
| Improvement (110) | Barrier (1100) | TiO₂/65.0 |
| | Improvement (1101) | |
| | Crystallisation (1102) | ZnₓSn_{y}O_{z}/5.0 |

| | |
|---|---|
| Conduction layer (112) | Ag/12.5 |
| Sacrificial layer (111b) | Ti/2.5 |
| Insertion layer (113) | ZnₓSn_{y}O_{z}/7.0 |
| Standardisation layer (114) | Ti/1.5 |
| Resistance (Ω/□) | 4.00 |
| Maximum luminance (a.u.) with green light | 454 |
| Maximum luminance (a.u.) with red light | 226 |
| Maximum luminance (a.u.) with blue light | 53 |

The support (10) is a clear glass with a geometric thickness equal to 100 nm.

Table III shows four columns with examples of electrodes (numbers of layers, chemical nature and thickness of layers) as well as the results of maximum luminance calculations expressed as arbitrary unit (a.u.) conducted using the to program SETFOS version 3 from Fluxim for a monochromic radiation of red, green and blue light in accordance with FIGS. 10, 11 and 12 respectively for an organic light-emitting device incorporating these substrates. The general structure of the organic light-emitting device has been described above (p. 32, 1. 8 to p. 33, 1. 5). Examples 1R and 2R are two examples of substrates not in conformity with the invention respectively on a glass with a refractive index with a value equal to 1.5 and on a glass with a refractive index equal to 2.0 at a wavelength of 550 nm. Examples 1R and 2R are transparent substrates having electrodes based on an architectural low-emission lamination structure having a conduction layer of Ag (112) comprising a layer for standardising surface electrical properties (114), wherein the thickness of the improvement coating (110) has not been optimised. In these examples, the improvement coating (110) comprises a barrier layer (1100), which is merged with an improvement layer (1101) and this layer is covered by a crystallisation layer (1102). Moreover, the crystallisation (1102) and insertion (113) layers are of the same nature. These layers are made of ZnₓSn_{y}O_{z} (where x+y≧3 and z≦6), the ZnₓSn_{y}O_{z} comprising at most 95% by weight of zinc, the percentage by weight of zinc being expressed in relation to the total weight of the metals present in the layer. Examples 3 and 4 illustrate transparent substrates in conformity with the invention respectively on a glass with a refractive index with a value equal to 1.5 and on a glass with a refractive index equal to 2 at a wavelength of 550 nm. In these examples, the improvement coating (110) has an optical thickness complying with equation:

T_{ME}=T_{ME}_{_{—}}ₒ+[B*sin(π*T_{D1}/T_{D1}_{_{—}}ₒ)]/(nₛᵤₚₚₒᵣₜ)³

and this has a barrier layer (1100), which is merged with an improvement layer (1101) and this layer is covered by a crystallisation layer (1102). Moreover, the crystallisation (1102) and insertion (114) layers are of the same nature. These layers are made of ZnₓSn_{y}O_{z} (where x+y≧3 and z≦6), the ZnₓSn_{y}O_{z} preferably comprising at most 95% by weight of zinc, the percentage by weight of zinc being expressed in relation to the total weight of the metals present in the layer.

Comparison of the different columns of Table III also clearly demonstrates the advantages provided by the transparent substrate according to the invention. In fact, depending on the colour emitted by the light source, it is evident that an increase of at least 11% of the luminance can be obtained when using glass with a high index (example 2R and example 4R in the case of blue light, glass with index 2.0) and at least 36% of the luminance can be obtained when using glass with a lower index (example 1R and example 3 in the case of blue light, glass with index 1.5). In other words, an increase in luminance is observed irrespective of the refractive index of the support used.

TABLE III

| | | Examples | | | |
|---|---|---|---|---|---|
| | | 1R | 2R | 3 | 4 |
| | | Refractive index of support | | | |
| | | 1.5 | 2 | 1.5 | 2 |
| | | Nature/ | Nature/ | Nature/ | Nature/ |
| | | thickness | thickness | thickness | thickness |
| Coating | Layers | (nm) | (nm) | (nm) | (nm) |
| Improvement | Barrier | TiO₂/20.0 | TiO₂/20.0 | TiO₂/65.0 | TiO₂/65.0 |
| (110) | (1100) | | | | |
| | Improvement | | | | |
| | (1101) | | | | |
| | Crystallisation | ZnₓSn_{y}O_{z}/5.0 | ZnₓSn_{y}O_{z}/5.0 | ZnₓSn_{y}O_{z}/5.0 | ZnₓSn_{y}O_{z}/5.0 |
| | (1102) | | | | |

| | | | | |
|---|---|---|---|---|
| Conduction layer (112) | Ag/12.5 | Ag/12.5 | Ag/12.5 | Ag/12.5 |
| Sacrificial layer (111b) | Ti/2.5 | Ti/2.5 | Ti/2.5 | Ti/2.5 |
| Insertion layer (113) | ZnₓSn_{y}O_{z}/ | ZnₓSn_{y}O_{z}/ | ZnₓSn_{y}O_{z}/ | ZnₓSn_{y}O_{z}/ |
| | 14.0 | 14.0 | 14.0 | 14.0 |
| Standardisation layer (114) | Ti nitride/ | Ti nitride/ | Ti/1.5 | Ti/1.5 |
| | 1.5 | 1.5 | | |
| Resistance (Ω/□) | 4.00 | 4.00 | 4.00 | 4.00 |
| Maximum luminance (a.u.) | 302 | 653 | 454 | 734 |
| with green light | | | | |
| Maximum luminance (a.u.) | 153 | 318 | 226 | 358 |
| with red light | | | | |
| Maximum luminance (a.u.) | 39 | 80 | 53 | 89 |
| with blue light | | | | |

The support (10) is a clear glass with a geometric thickness equal to 100 nm.

As described above, the transparent substrate according to the invention has a coating for improving the light transmission (110) comprising at least one additional crystallisation layer. This layer allows a preferred growth of the metal layer, e.g. of silver, forming the metal conduction layer and thus allows favourable electrical and optical properties of the metal conduction layer to be obtained. It comprises at least one inorganic chemical compound. The inorganic chemical compound forming the crystallisation layer does not necessarily have a high refractive index. The inorganic chemical compound comprises at least ZnOₓ (where x≦1) and/or ZnₓSn_{y}O_{z} (where x+y≧3 and z≦6). ZnₓSn_{y}O_{z} preferably comprises at most 95% by weight of zinc, the percentage by weight of zinc being expressed in relation to the total weight of the metals present in the layer. Surprisingly, the inventors have found that the thickness of the crystallisation layer must be adapted or increased to provide a metal conduction layer with good conduction and very low absorption. In fact, the layer having properties for improving light transmission (1101) has a greater thickness than that usually encountered in the field of multilayer conductive coatings (e.g. low emission type coating). In the case of a low-emission coating, the geometric thickness of the layer localized between the support (10) and the crystallisation layer (1102) is at most 30.0 nm, generally in the order of 20.0 nm, and the geometric thickness of the crystallisation layer is in the order of 5.0 nm. The inventors have determined that a geometric thickness of this type is sufficient to obtain a conduction layer that has good conduction and allows a transparent substrate according to the invention with a resistance by square of less than 5 Ω/□ to be obtained. However, the inventors have determined that the geometric thickness of the crystallisation layer must preferably be at least equal to 7 nm, more preferred at least equal to 10 nm, in order to obtain a lower resistance expressed in flip. The geometric thickness of the crystallisation layer (1102) must therefore be at least equal to 7% of the sum of the thicknesses of the barrier layer (1100) and the layer for improving light transmission (1102), preferably 11%, more preferred 14%. Moreover, the optical thickness of the improvement coating (110) lies within the optical thickness range complying with equation:

T_{ME}=T_{ME}_{_{—}}ₒ+[B*sin(πT_{D1}/T_{D1}_{_{—}}ₒ)]/(nₛᵤₚₚₒᵣₜ)³

The sum of the optical thicknesses of the layer having properties for improving the light transmission (1101) and the barrier layer (1100) must be reduced if the optical thickness of the crystallisation layer (1102) is increased.

Table IV shows three columns with examples of transparent substrates having different types of electrodes (numbers of layers, chemical nature and thickness of layers) and the measurement results of resistance expressed in Ω/□. The general structure of the organic light-emitting device has been described above (p. 39, 1. 26 to p. 40, 1. 9). Example 1R is a transparent substrate not in conformity with the invention having an electrode based on an architectural low-emission lamination structure with a conduction layer of Ag (112) comprising a layer for standardising surface electrical properties (114), wherein the thickness of the improvement coating (110) has not been optimised. In these examples, the improvement coating (110) comprises a barrier layer (1100), which is merged with an improvement layer (1101) and this layer is covered by a crystallisation layer (1102). Moreover, the crystallisation (1102) and insertion (113) layers are of the same nature. These layers are made of ZnₓSn_{y}O_{z} (where x+y≧3 and z≦6), the ZnₓSn_{y}O_{z}, comprising at most 95% by weight of zinc, the percentage by weight of zinc being expressed in relation to the total weight of the metals present in the layer. Examples 2 and 3 illustrate transparent substrates in conformity with the invention. In these examples, the improvement coating (110) has an optical thickness complying with equation:

T_{ME}=T_{ME}_{_{—}}ₒ+[B*sin(π*T_{D1}/T_{D1}_{_{—}}ₒ)]/(nₛᵤₚₚₒᵣₜ)³

and this has a barrier layer (1100), which is merged with an improvement layer (1101) and this layer is covered by a crystallisation layer (1102). Moreover, the crystallisation (1102) and insertion (114) layers are of the same nature. These layers to are made of ZnₓSn_{y}O_{z} (where x+y≧3 and z≦6), the ZnₓSn_{y}O_{z} preferably comprising at most 95% by weight of zinc, the percentage by weight of zinc being expressed in relation to the total weight of the metals present in the layer. Example 3 illustrates a transparent substrate in accordance with the invention having an electrode that is optimised with respect to the geometric thickness of the crystallisation layer (1102).

TABLE IV

| | | Examples | | |
|---|---|---|---|---|
| | | 1R | 2 | 3 |
| | | Nature/ | Nature/ | Nature/ |
| | | thickness | thickness | thickness |
| Coating | Layers | (nm) | (nm) | (nm) |
| Improvement | Barrier | TiO₂/20.0 | TiO₂/65.0 | TiO₂/60.0 |
| (110) | (1100) | | | |
| | Improvement | | | |
| | (1101) | | | |
| | Crystallisation | ZnₓSn_{y}O_{z}/ | ZnₓSn_{y}O_{z}/ | ZnₓSn_{y}O_{z}/ |
| | (1102) | 5.0 | 5.0 | 10.0 |

| | | | |
|---|---|---|---|
| Conduction layer (112) | Ag/12.5 | Ag/12.5 | Ag/12.5 |
| Sacrificial layer (111b) | Ti/2.5 | Ti/2.5 | Ti/2.5 |
| Insertion layer (113) | ZnₓSn_{y}O_{z}/ | ZnₓSn_{y}O_{z}/ | ZnₓSn_{y}O_{z}/ |
| | 7.0 | 7.0 | 7.0 |
| Standardisation layer (114) | Ti nitride/1.5 | Ti nitride/1.5 | Ti nitride/1.5 |
| Resistance (Ω/□) | 3.78 | 4.09 | 3.91 |

The support (10) is a clear glass with a geometric thickness equal to 1.60 mm.

As described above, the transparent substrate according to the invention has an electrode that has at least one additional insertion layer (113). The function of this insertion layer (113) is to form part of an optical cavity that enables the metal conduction layer to become transparent. In fact, it is known to a person skilled in the art optimising low-emission multilayer coatings, for example, that the use of an insertion layer with a geometric thickness of at least 15.0 nm is necessary to make the conduction layer transparent. On the other hand, no conductivity condition is imposed to obtain optical transparency values compatible with architectural applications. The layers developed for architectural application cannot be used directly for optoelectronic applications, since they generally contain dielectric compounds and/or poorly conductive compounds.

The inventors have surprisingly determined that the geometric thickness of the insertion layer (Eᵢₙ) (113) is such that, firstly, its ohmic thickness is at most equal to 10¹² ohm, preferably at most equal to 10⁴ ohm, wherein the ohmic thickness is equal to the relation between the resistivity of the material forming the insertion layer (ρ), on the one hand, and the geometric thickness of this same layer (1), on the other; and secondly, the geometric thickness of the insertion layer (113) is linked to the geometric thickness of the first organic layer of the organic light-emitting device (E_{org}), the term “first organic layer” denoting all the organic layers disposed between the insertion layer (113) and the organic light-emitting layer. The inventors have thus surprisingly found, as indicated in FIG. 20, that two areas characterised by the luminance maxima were observed:

the first area corresponding to the equation: E_{org}=Eᵢₙ−A, where A is a constant having a value in the range of 5.0 to 75.0 nm, preferably from 20.0 to 60.0 nm, more preferred from 30.0 to 45.0 nm.

the second area corresponding to the equation: E_{org}=Eᵢₙ−C, where C is a constant having a value in the range of 150.0 to 250.0 nm, preferably from 160.0 to 225.0 nm, more preferred from 75.0 to 205.0 nm.

The inventors have thus found that the equations E_{org}=−A or E_{org}=Eᵢₙ−C allow the geometric thickness of the first organic layer of the organic light-emitting device to be used to optimise the optical parameters (geometric thickness and refractive index) of the insertion layer and therefore to optimise the amount of light transmitted while retaining a thickness of the insertion layer that is compatible with the electrical properties that enable high ignition voltages, i.e. respectively for a first and a second luminance maximum, to be avoided.

Moreover, the use of a dielectric, i.e. poorly conductive, layer for contact between the conduction layer and the organic portion of the organic light-emitting device runs counter to the customarily accepted knowledge of a skilled person who has to manufacture organic light-emitting devices. The inventors have surprisingly found that the use of a dielectric, i.e. poorly conductive, material does not have to be excluded for the formation of the insertion layer (113). However, a conductive material is preferred. In fact, if the insertion layer has too high an ohmic thickness, the voltages of use increase considerably, as shown in Table V.

Table V shows two columns with examples of transparent substrates having different types of electrodes (numbers of layers, chemical nature and thickness of layers) as well as the results of measurements of electrical and optical performance obtained by means of the organic light-emitting device in which these substrates are incorporated. The general structure of the organic light-emitting device has been described above (p. 39, 1. 26 to p. 40, 1. 9). Example 1R is a transparent substrate comprising an electrode based on an architectural low-emission lamination structure having a conduction layer of Ag (112). Example 1R is therefore a transparent substrate that is not in conformity with the invention because it has an electrode that is not optimised for an OLED. The electrode of the substrate 1R has a standardisation layer (114) and a coating for improving light transmission (110), of which the optical thickness has not been optimised and therefore lies outside the thickness range complying with equation:

T_{ME}=T_{ME}_{_{—}}ₒ+[B*sin(π*T_{D1}/T_{D1}_{_{—}}ₒ)]/(nₛᵤₚₚₒᵣₜ)³

In example 1R the improvement coating (110) comprises a barrier layer (1100), which is merged with an improvement layer (1101) and this layer is covered by a crystallisation layer (1102). Moreover, the crystallisation (1102) and insertion (113) layers are of the same nature. These layers are made of ZnₓSn_{y}O_{z} (where x+y≧3 and z≦6), the ZnₓSn_{y}O_{z} comprising at most 95% by weight of zinc, the percentage by weight of zinc being expressed in relation to the total weight of the metals present in the layer. Moreover, example 1R also shows an insertion layer (113) with a geometric thickness that has not been optimised. Example 2 illustrates an electrode in conformity with the invention. In this example, the improvement coating (2) has an optical thickness complying with equation:

T_{ME}=T_{ME}_{_{—}}ₒ+[B*sin(π*T_{D1}/T_{D1}_{_{—}}ₒ)]/(nₛᵤₚₚₒᵣₜ)³

and this has a barrier layer (1100), which is merged with an improvement layer (1101) and this layer is covered by a crystallisation layer (1102). Moreover, the crystallisation (1102) and insertion (114) layers are of the same nature. These layers are made of ZnₓSn_{y}O_{z} (where x+y≧3 and z≦6), the ZnₓSn_{y}O_{z} preferably comprising at most 95% by weight of zinc, the percentage by weight of zinc being expressed in relation to the total weight of the metals present in the layer. It is evident that the electrical properties of example 2 are appreciably higher than those shown in example 1R, which is a comparative example.

TABLE V

| | | Examples | |
|---|---|---|---|
| | | 1R | 2 |
| | | Nature/thickness | Nature/thickness |
| Coating | Layers | (nm) | (nm) |
| Improvement | Barrier | TiO₂/20.0 | TiO₂/65.0 |
| (110) | (1100) | | |
| | Improvement | | |
| | (1101) | | |
| | Crystallisation | ZnₓSn_{y}O_{z}/5.0 | ZnₓSn_{y}O_{z}/5.0 |
| | (1102) | | |

| | | |
|---|---|---|
| Conduction layer (112) | Ag/12.5 | Ag/12.5 |
| Sacrificial layer (111b) | Ti/2.5 | Ti/2.5 |
| Insertion layer (113) | ZnₓSn_{y}O_{z}/14.0 | ZnₓSn_{y}Oₓ/7.0 |
| Standardisation layer (114) | — | Ti nitride/1.5 |
| Resistance (Ω/□) | 4.00 | 4.09 |
| Electrical performance | | |
| V at 10 mA/cm² | 4.45 | 2.70 |
| V at 100 mA/cm² | 5.60 | 3.55 |
| Optical performance | | |
| V at 1000 cd/m² | 4.10 | 2.55 |
| V at 10000 cd/m² | 5.00 | 2.85 |

The support (10) is a clear glass with a geometric thickness equal to 1.60 mm.

Finally, Table VI shows that with a constant geometric thickness of the insertion layer, it is possible to reduce the voltages of use, decreasing the resistivity of this layer. In fact, Table VI shows three columns with examples of transparent substrates, which are in accordance with the invention but differ from one another with respect to the nature of the chemical compound forming the insertion layer, as well as the results of measurements of electrical and optical performance obtained by means of the organic light-emitting device in which these electrodes are incorporated. The general structure of the organic light-emitting device has been described above (p. 39, 1. 26 to p. 40, 1. 9). Example 1 illustrates a transparent substrate according to the invention that has an electrode with an insertion layer comprising a conductive layer made of zinc oxide doped with aluminium (resistivity of ZnO:Al:10⁻⁴ Ω*cm). Example 2 illustrates a transparent substrate according to the invention that has an electrode with an insertion layer comprising a poorly conductive layer made of ZnₓSn_{y}O_{z} (where x+y≧3 and z≦6), the ZnₓSn_{y}O_{z} preferably comprising at most 95% by weight of zinc, the percentage by weight of zinc being expressed in relation to the total weight of the metals present in the layer (resistivity of ZnₓSn_{y}O_{z}:10⁻² Ω*cm). Example 3 illustrates a transparent substrate according to the invention that has an electrode with an insertion layer comprising a dielectric layer of titanium dioxide (resistivity of TiO₂:70 10⁴ Ω*cm).

It is evident that to reach a current level of 100 mA, the voltage to be applied is lower in the case of a conductive insertion layer with a layer made from a conductive material than in the case of a layer made from a dielectric material.

TABLE VI

| | | Examples | | |
|---|---|---|---|---|
| | | 1 | 2 | 3 |
| | | Nature/ | Nature/ | Nature/ |
| | | thickness | thickness | thickness |
| Coating | Layers | (nm) | (nm) | (nm) |
| Improvement | Barrier | TiO₂/65.0 | TiO₂/65.0 | TiO₂/65.0 |
| (110) | (1100) | | | |
| | Improvement | | | |
| | (1101) | | | |
| | Crystallisation | ZnₓSn_{y}O_{z}/ | ZnₓSn_{y}O_{z}/ | ZnₓSn_{y}O_{z}/ |
| | (1102) | 5.0 | 5.0 | 5.0 |

| | | | |
|---|---|---|---|
| Conduction layer (112) | Ag/12.5 | Ag/12.5 | Ag/12.5 |
| Sacrificial layer (111b) | Ti/2.5 | Ti/2.5 | Ti/2.5 |
| Insertion layer (113) | ZnO:Al/7.0 | ZnₓSn_{y}O_{z}/ | TiO₂/7.0 |
| | | 7.0 | |
| Standardisation layer (114) | Ti nitride/1.5 | Ti nitride/1.5 | Ti nitride/1.5 |
| Electrical performance | 2.98 | 3.55 | 3.98 |
| V at 100 mA/cm² | | | |

The support (10) is a clear glass with a geometric thickness equal to 1.60 mm.

Table VII shows organic light-emitting devices that emit a quasi-white light. The general structure of the organic light-emitting device has been described above (p. 40, I. 9 to I. 29). Example 1R is a transparent substrate comprising an electrode based on an architectural low-emission lamination structure having a conduction layer of Ag. Example 1R is a transparent substrate that comprises an electrode that is not optimised for an OLED having a standardisation layer (114) and wherein the thickness of the improvement coating (110) has not been optimised and therefore lies outside the thickness range complying with equation:

T_{ME}=T_{ME}_{_{—}}ₒ+[B*sin(π*T_{D1}/T_{D1}_{_{—}}ₒ)]/(nₛᵤₚₚₒᵣₜ)³

In example 1R the improvement coating (110) comprises a barrier layer (1100), which is merged with an improvement layer (1101) and this layer is covered by a crystallisation layer (1102). Moreover, the crystallisation (1102) and insertion (113) layers are of the same nature. These layers are made of ZnₓSn_{y}O_{z} (where x+y≧3 and z≦6), the ZnₓSn_{y}O_{z} comprising at most 95% by weight of zinc, the percentage by weight of zinc being expressed in relation to the total weight of the metals present in the layer. Examples 2 and 3 show examples in conformity with the invention. In these examples, the improvement coating (2) has an optical thickness complying with equation:

T_{ME}=T_{ME}_{_{—}}ₒ+[B*sin(π*T_{D1}/T_{D1}_{_{—}}ₒ)]/(nₛᵤₚₚₒᵣₜ)³

and this has a barrier layer (1100), which is merged with an improvement layer (1101) and this layer is covered by a crystallisation layer (1102). Moreover, the crystallisation (1102) and insertion (114) layers are of the same nature. These layers are made of ZnₓSn_{y}O_{z} (where x+y≧3 and z≦6), the ZnₓSn_{y}O_{z} preferably comprising at most 95% by weight of zinc, the percentage by weight of zinc being expressed in relation to the total weight of the metals present in the layer. Moreover, example 2 more particularly illustrates a transparent substrate having a fine metal layer and having a more significant thickness of coating for improving light transmission properties. The advantage of such thickness of the improvement coating is that:

it allows, on the one hand, better protection of the metal conduction layer against any contamination of said layer by migration of pollutants coming from the substrate, in the present case migration of alkaline substances originating from the glass substrate,

on the other hand, it allows less precious metal to be used for the formation of the metal conduction layer.

Example 3 illustrates a transparent substrate having a thick silver layer that allows a conduction layer with a low resistance to be obtained.

Comparison of the properties obtained for devices emitting quasi-white light incorporating a transparent substrate according to examples 1R, 2 and 3 demonstrates that:

the service lives of the devices comprising a substrate according to the invention are longer compared to example 1R, but also compared to a transparent substrate consisting of an identical support (10) and with an electrode of ITO disposed on top of it that has a geometric thickness equal to 90 nm, the service life of which amounts to 162 hours (result not established in Table VII);

the surface resistance (Ω/□) of example 3 having a thick conduction layer is at least half as low as the surface resistance (SIM) of examples 2 and 1R, and this property provides the possibility of forming devices of larger dimensions without using any conduction reinforcement such as a metal grid, for example;

the optical performance levels achieved with organic light-emitting devices with examples of transparent substrates according to the invention (example 2 and 3) are higher than those obtained with the comparative example 1R. In fact the voltage applied to obtain the same light intensity is lower in examples 2 and 3 than in example 1R.

TABLE VII

| | | Examples | | |
|---|---|---|---|---|
| | | 1R | 2 | 3 |
| | | Nature/ | Nature/ | Nature/ |
| | | thickness | thickness | thickness |
| Coating | Layers | (nm) | (nm) | (nm) |
| Improvement | Barrier | TiO₂/20.0 | TiO₂/65.0 | TiO₂/20.0 |
| (110) | (1100) | | | |
| | Improvement | | | |
| | (1101) | | | |
| | Crystallisation | ZnₓSn_{y}O_{z}/ | ZnₓSn_{y}O_{z}/ | ZnₓSn_{y}O_{z}/ |
| | (1102) | 5.0 | 5.0 | 5.0 |

| | | | |
|---|---|---|---|
| Conduction layer (112) | Ag/12.5 | Ag/12.5 | Ag/23.0 |
| Sacrificial layer (111b) | Ti/2.5 | Ti/2.5 | Ti/2.5 |
| Insertion layer (113) | ZnₓSn_{y}O_{z}/ | ZnₓSn_{y}O_{z}/ | ZnₓSn_{y}O_{z}/ |
| | 7.0 | 7.0 | 7.0 |
| Standardisation layer (114) | Ti nitride/1.5 | Ti nitride/1.5 | Ti nitride/1.5 |
| Resistance (Ω/□) | 3.78 | 4.09 | 1.80 |
| Electrical performance | | | |
| V at 2 mA/cm² | 9.7-10.4 | 9.2-9.4 | 10.1-10.5 |
| cd/A at 100 cd/m² | 37.7-39.0 | 39.8 | 56.9 |
| cd/A at 1000 cd/m² | 56.9-59.3 | 63.3 | 56.5 |
| Optical performance | | | |
| V at 1000 cd/m² | 8.70 | 7.90 | 8.29 |
| V at 10000 cd/m² | 10.25 | 9.12 | 10.06 |
| Colour expressed as chromatic | (0.44; 0.40) | (0.43; 0.41) | (0.41; 0.38) |
| coordinates (x, y at 0° | | | |
| in the 1931 CIE colorimetric | | | |
| diagram (x, y) | | | |
| Service life (in hours) | 166 | 625 | 739 |
| measured at 30 mA/cm² | | | |

The support (10) is a clear glass with a geometric thickness equal to 1.60 mm.

The electrical performance levels are measured by applied voltages (V) to obtain a current of 2 mA/cm². The optical performance levels are measured by applied voltages (V) to obtain either a light intensity of 1000 cd/m² or 10000 cd/m².

1. A transparent substrate, comprising:
a support, and
an electrode,
wherein the electrode comprises a lamination structure comprising a single metal conduction layer and at least one coating having properties for improving light transmission through the electrode,
wherein the coating has a geometric thickness at least more than 3.0 nm and at most less than or equal to 200 nm,
wherein the coating comprises at least one layer suitable for improving light transmission between the metal conduction layer and the support, on which the electrode is deposited,
wherein an optical thickness of the coating T_{D1}, and a geometric thickness of the metal conduction layer, T_{ME}, are linked by an equation:
T_{ME}=T_{ME}_{_{—}}ₒ+[B*sin(π*T_{D1}/T_{D1}_{_{—}}ₒ)/(nₛᵤₚₚₒᵣₜ)³,
wherein T_{ME}_{_{—}}ₒ, B, and T_{D1}_{_{—}}ₒ are constants with T_{ME}_{_{—}}ₒ having a value in a range of 10.0 to 25.0 nm, B having a value in a range of 10.0 to 16.5 nm, and T_{D1}_{_{—}}ₒ having a value in a range of 23.9*n_{D1} to 28.3*n_{D1} nm, with n_{D1} representing a refractive index of the coating at a wavelength of 550 nm, and nₛᵤₚₚₒᵣₜ representing a refractive index of the support at a wavelength of 550 nm.

2. The transparent substrate of claim 1, wherein the support has a refractive index, nₛᵤₚₚₒᵣₜ, with a value at least equal to 1.2 at a wavelength of 550 nm.

3. The transparent substrate of claim 1, wherein the refractive index of the coating is higher than the refractive index of the support.

4. The transparent substrate of claim 1, wherein the support has a refractive index in a range of between 1.4 and 1.6 at a wavelength of 550 nm.

5. The substrate of claim 4, wherein the geometric thickness of the metal conduction layer is at least equal to 16.0 nm and at most equal to 29.0 nm, and
wherein the geometric thickness of the coating is at least equal to 20.0 nm and at most equal to 40.0 nm.

6. The substrate of claim 1, wherein the support has a refractive index equal to 1.5 with a wavelength of 550 nm,
wherein the geometric thickness of the metal conduction layer is at least equal to 6.0 nm and at most equal to 22.0 nm, and
wherein the geometric thickness of the coating is at least equal to 50.0 nm and at most equal to 130.0 nm.

7. The substrate of claim 1, wherein the electrode comprises a second coating which improves light transmission comprising at least one additional crystallisation layer,
wherein, in relation to the support, the crystallisation layer is the layer furthest removed from the lamination structure forming the coating.

8. The substrate of claim 7, wherein the geometric thickness of the crystallisation layer is at least equal to 7% of the total geometric thickness of the second coating.

9. The substrate of claim 1, wherein the electrode has comprises a thin layer which standardizes at least one surface electrical property, which, in relation to the support, lies at the top of the multilayer lamination structure forming the electrode.

10. The substrate of claim 1, wherein the electrode has comprises at least one additional insertion layer located between the metal conduction layer and the thin layer.

11. The substrate of claim 10, wherein a geometric thickness of the insertion layer, Eᵢₙ, is such that an ohmic thickness of the insertion layer is at most equal to 10¹² ohm,
wherein the ohmic thickness is equal to a relation between a resistivity of material forming the insertion layer, p, on the one hand, and the geometric thickness of the insertion layer, 1, on the other, and
wherein the geometric thickness of the insertion layer is linked to a geometric thickness of a first organic layer of an organic light-emitting device, E_{org}, wherein the term “first organic layer” denotes all organic layers disposed between the insertion layer and an organic light-emitting layer, by an equation:
E_{org}=Eᵢₙ−A,
wherein A is a constant having a value in a range of 5.0 to 75.0 nm.

12. The substrate of claim 10, wherein the geometric thickness of the insertion layer, (Eᵢₙ), is such that an ohmic thickness of the insertion layer is at most equal to 10¹² ohm,
wherein the ohmic thickness is equal to a relation between a resistivity of material forming the insertion layer, p, on the one hand, and the geometric thickness of the insertion layer, 1, on the other, and
wherein the geometric thickness of the insertion layer is linked to 0 a geometric thickness of a first organic layer of an organic light-emitting device, E_{org}, wherein the term “first organic layer” denotes all organic layers disposed between the insertion layer and an organic light-emitting layer, by an equation:
E_{org}=Eᵢₙ−C,
wherein C is a constant having a value in a range of 150.0 to 250.0 nm.

13. The substrate of claim 1, wherein the metal conduction layer comprises at least one sacrificial layer on at least one face.

14. The substrate of claim 1, wherein the support, on which the electrode is deposited, comprises at least one functional coating on an opposite face from a face on which the electrode is deposited.

15. The substrate of claim 1, wherein a reflection of a support side, r_{support,} has a value at least equal to 28% and at most equal to 49%.

16. A process for manufacturing the substrate of claim 1, comprising:
(I) depositing the support of the coating having properties for improving light transmission; and
(II) depositing the metal conduction layer directly followed by depositing at least one different functional element, thereby forming a photonic system.

17. A process for manufacturing the substrate of claim 1, comprising:
(I) depositing the support of the coating having properties for improving light transmission through the electrode, the metal conduction layer, a sacrificial layer, and an insertion layer; and
(II) depositing a standardization layer directly followed by depositing at least one different functional element, thereby forming a photonic system.

18. An organic light-emitting device, comprising at least one substrate of claim 1.

19. The device of claim 18, which emits quasi-white light.

20. The transparent substrate of claim 2, wherein the refractive index of the coating is higher than the refractive index of the support.
